(19) United States
(12) Patent Application Publication
(10) Pub. No.: US 2013/0109253 A1
(43) Pub. Date: May 2, 2013

(54) TABLET DEVICE ENCLOSURE AND METHOD

(71) Applicants: WELDON GAMMON, Raleigh, NC (US); David Libman, Dove Canyon, CA (US); Jaysun Stockdell-Giesler, Morrisville, NC (US)

(72) Inventors: WELDON GAMMON, Raleigh, NC (US); David Libman, Dove Canyon, CA (US); Jaysun Stockdell-Giesler, Morrisville, NC (US)

(21) Appl. No.: 13/287,971

(22) Filed: Nov. 2, 2011

(51) Int. Cl. H01R 11/11; H05K 5/02; B23P 11/00

(52) U.S. Cl. 439/883; 29/592.1; 312/223.2

(57) ABSTRACT

An enclosure for tablet devices with features to provide secure mounting options is described. In accordance with at least one embodiment, the enclosure provides options to mount a tablet device in either a desktop stand or onto a variety of other supports, including VESA compliant mounts and electrical junction boxes. Security options include the ability to secure the tablet device inside the enclosure to provide a deterrent to theft or vandalism. Additional levels of security may be provided that limit access to the tablet device's control features (i.e., control buttons, cameras, sensors). In accordance with at least one embodiment, access to the tablet device's display, button(s), camera(s), microphone(s), speaker(s), connector(s), and/or tactile feedback of button(s) or other devices can be selectively maintained or prevented while the tablet device is enclosed in the tablet enclosure.

### BACKGROUND OF THE INVENTION

(1) Field of the Invention

The present invention relates to an enclosure for a tablet device or other electronic device.

(2) Background of the Invention

Tablet devices (“tablets”), such as the APPLE IPAD and GOOGLE ANDROID tablets, were originally designed to provide convenient mobile computing, communication, and entertainment services. They are typically lightweight, thin, include a high resolution touchscreen interface, and have network connectivity. Thousands of application programs have been released for tablets covering all areas, from media players to word processors to remote control programs.

Although tablets are intended to be portable devices, they can also be used at fixed locations, such as for providing remote control, entertainment, or communications interfaces in a residential or commercial environment. For example, tablets have the potential for replacing conventional dedicated touchscreen interfaces used in commercial and residential A/V control systems.

The portability that makes tablets useful as mobile computing devices is, however, a disadvantage when using tablets at fixed locations, particularly in public or commercial locations. Tablets do not generally have facilities for securing them to furniture or walls. They are vulnerable to being removed from their intended use location, either inadvertently or by malfeasance. This vulnerability to misplacement and theft has limited tablets' use as replacements for dedicated A/V touchscreen interfaces and other uses in public or semi-public locations.

### BRIEF SUMMARY OF THE INVENTION

In accordance with at least one embodiment, an enclosure for tablet devices with features to provide secure mounting options is described. In accordance with at least one embodiment, the enclosure provides options to mount a tablet device in either a desktop stand or onto a variety of other supports, including VESA compliant mounts and electrical junction boxes. Security options include the ability to secure the tablet device inside the enclosure to provide a deterrent to theft or vandalism. Optionally, additional levels of security may be provided that limit access to the tablet device's control features (i.e., control buttons, cameras, sensors) to prevent unauthorized or accidental activation of these controls. In accordance with at least one embodiment, access to the tablet device's display, button(s), camera(s), microphone(s), speaker(s), connector(s), and/or tactile feedback of button(s) or other devices can be selectively maintained or prevented while the tablet device is enclosed in the tablet enclosure.

### BRIEF DESCRIPTION OF THE DRAWINGS

The present invention may be better understood, and its features made apparent to those skilled in the art by referencing the accompanying drawings.

FIG. 1 is a front view of a tablet enclosure and stand in accordance with an exemplary embodiment.

FIG. 2 is a side view of a tablet enclosure and stand in accordance with an exemplary embodiment.

FIG. 3 is a rear view of a tablet enclosure and stand in accordance with an exemplary embodiment.

FIG. 4 is a front perspective view of a tablet enclosure and stand in accordance with an exemplary embodiment.

FIG. 5 is a rear perspective view of a tablet enclosure and stand in accordance with an exemplary embodiment.

FIG. 6 is an exploded rear perspective view of a tablet enclosure and stand in accordance with an exemplary embodiment.

FIG. 7 is a rear perspective view of a tablet enclosure and stand in accordance with an exemplary embodiment.

FIG. 8 is a front perspective view of a tablet enclosure and stand in accordance with an exemplary embodiment in an inclined position.

FIG. 9 is a front view of a tablet enclosure in accordance with an exemplary embodiment.

FIG. 10 is a side view of a tablet enclosure in accordance with an exemplary embodiment.

FIG. 11 is a rear view of a tablet enclosure in accordance with an exemplary embodiment.

FIG. 12 is a front perspective view of a tablet enclosure in accordance with an exemplary embodiment.

FIG. 13 is a rear perspective view of a tablet enclosure in accordance with an exemplary embodiment.

FIG. 14 is an exploded front perspective view of a tablet enclosure in accordance with an exemplary embodiment.

FIG. 15 is a perspective view of a reorienting electrical connector assembly in accordance with an exemplary embodiment.

FIG. 16 is a perspective view of a reorienting electrical connector assembly housing in accordance with an exemplary embodiment.

FIG. 17 is a perspective view of a reorienting electrical connector assembly housing in accordance with an exemplary embodiment connected to a cable.

FIG. 18 is a rear perspective view of a tablet enclosure and stand in accordance with an exemplary embodiment.

FIG. 19 is an exploded cutaway view showing a configuration of an electrical connector assembly connected to a tablet device inside of a tablet enclosure in accordance with an exemplary embodiment.

FIG. 20 is a perspective view of a rear housing of a tablet enclosure in accordance with an exemplary embodiment.

FIG. 21 is an exploded front perspective view of a rear housing and front retention plate of a tablet enclosure in accordance with an exemplary embodiment.

FIG. 22 is an exploded front perspective view of a rear housing and front retention plate of a tablet enclosure in accordance with an exemplary embodiment.

FIG. 23 is a front view of a rear housing of a tablet enclosure in accordance with an exemplary embodiment.

FIG. 24 is an exploded front perspective view of a rear housing of a tablet enclosure in accordance with an exemplary embodiment.

FIG. 25 is a front view of a rear housing of a tablet enclosure in accordance with an exemplary embodiment.

FIG. 26 is a front view of a tablet enclosure in accordance with an exemplary embodiment.

FIG. 27 is a front perspective view of a tablet enclosure in accordance with an exemplary embodiment.

FIG. 28 is a rear perspective view of a tablet enclosure in accordance with an exemplary embodiment.

FIG. 29 is a cross sectional view of a portion of a tablet enclosure comprising a control linkage in accordance with an exemplary embodiment.

FIG. 30 is a rear perspective view of a portion of a tablet enclosure in accordance with an exemplary embodiment comprising a control linkage.

FIG. 31 is a front perspective view of a tablet enclosure in accordance with an exemplary embodiment.

FIG. 32 is an exploded front perspective view of a tablet enclosure in accordance with an exemplary embodiment.

FIG. 33 is a rear perspective view of a tablet enclosure in accordance with an exemplary embodiment.

FIG. 34 is an exploded front perspective view of a tablet enclosure in accordance with an exemplary embodiment.

FIG. 35 is an exploded rear perspective view of a tablet enclosure in accordance with an exemplary embodiment.

FIG. 36 is a rear perspective view of a tablet enclosure and stand in accordance with an exemplary embodiment.

FIG. 37 is a bottom view of a tablet enclosure and stand in accordance with an exemplary embodiment.

FIG. 38 is a rear perspective view of a tablet enclosure and stand in accordance with an exemplary embodiment.

FIG. 39 is a bottom perspective view of a tablet enclosure and stand in accordance with an exemplary embodiment.

FIG. 40 is a perspective view of an embodiment of a reinforcing mounting plate of the invention.

FIG. 41 is a perspective view of a reorienting electrical connector assembly in accordance with an exemplary embodiment.

FIG. 42 is a top view of a reorienting electrical connector assembly in accordance with an exemplary embodiment.

FIG. 43 is a side view of a reorienting electrical connector assembly in accordance with an exemplary embodiment.

FIG. 44 is a cutaway rear perspective view of a stand for a tablet enclosure in accordance with at least one embodiment.

FIG. 45 is a front view of a tablet enclosure in accordance with at least one embodiment.

FIG. 46 is a front perspective view of a tablet enclosure in accordance with at least one embodiment.

FIG. 47 is a detail view of a portion of a tablet enclosure in accordance with at least one embodiment.

FIG. 48 is detail cross sectional view of a portion of a tablet enclosure in accordance with at least one embodiment.

FIG. 49 is a side view of a tablet enclosure in accordance with at least one embodiment.

FIG. 50 is a top view of a tablet enclosure in accordance with at least one embodiment.

FIG. 51 is a bottom view of a tablet enclosure in accordance with at least one embodiment.

FIG. 52 is a rear view of a tablet enclosure in accordance with at least one embodiment.

FIG. 53 is a rear perspective view of a tablet enclosure in accordance with at least one embodiment.

FIG. 54 is a front perspective view of a rear housing of a tablet enclosure suitable for mounting on a surface using an electrical box in accordance with at least one embodiment.

FIG. 55 is a rear perspective view of a rear housing of a tablet enclosure suitable for mounting on a surface using an electrical box in accordance with at least one embodiment.

FIG. 56 is a side view of a tablet enclosure for mounting on a surface using an electrical box in accordance with at least one embodiment.

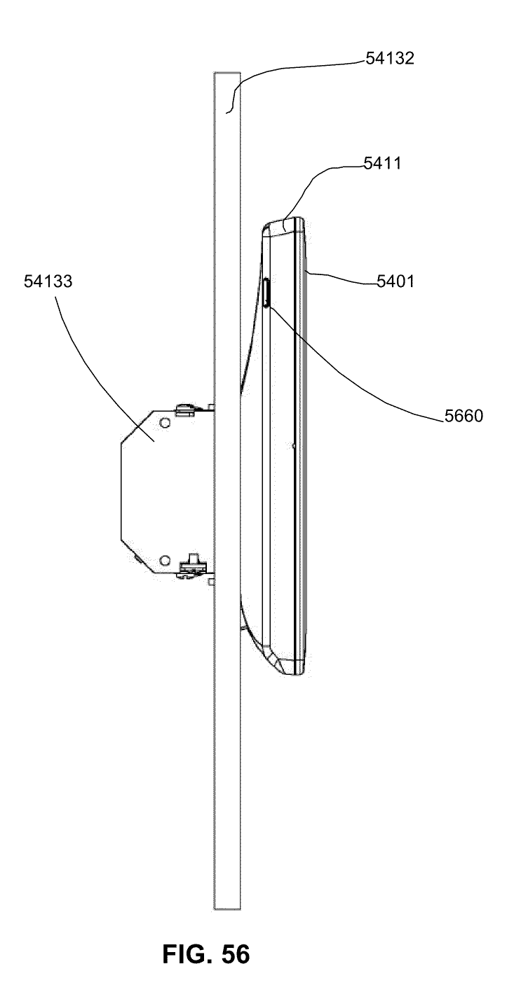

FIG. 57 is a rear view of a reorienting connector assembly in accordance with at least one embodiment.

FIG. 58 is a top view of a reorienting connector assembly in accordance with at least one embodiment.

FIG. 59 is a side view of a reorienting connector assembly in accordance with at least one embodiment.

FIG. 60 is a top view of a reorienting connector assembly in accordance with at least one embodiment.

FIG. 61 is a side view of a reorienting docking connector assembly in accordance with at least one embodiment.

FIG. 62 is a rear view of a tablet enclosure in accordance with at least one embodiment.

FIG. 63 is a side view of a tablet enclosure in accordance with at least one embodiment.

FIG. 64 is a side view of a tablet enclosure in accordance with at least one embodiment.

FIG. 65 is a top view of a tablet enclosure in accordance with at least one embodiment.

FIG. 66 is a bottom view of a tablet enclosure in accordance with at least one embodiment.

FIG. 67 is a front view of a tablet enclosure in accordance with at least one embodiment.

FIG. 68 is a top view of a control linkage for a tablet enclosure in accordance with at least one embodiment.

FIG. 69 is a side view of a control linkage for a tablet enclosure in accordance with at least one embodiment.

FIG. 70 is a perspective view of a control linkage for a tablet enclosure in accordance with at least one embodiment.

FIG. 71 is a rear perspective view of a tablet enclosure in accordance with at least one embodiment.

FIG. 72 is a front view of a tablet enclosure in accordance with at least one embodiment.

FIG. 73 is a side view of a tablet enclosure in accordance with at least one embodiment.

FIG. 74 is a side view of a tablet enclosure in accordance with at least one embodiment.

FIG. 75 is a top view of a tablet enclosure in accordance with at least one embodiment.

FIG. 76 is a bottom view of a tablet enclosure in accordance with at least one embodiment.

FIG. 77 is a front perspective view of a tablet enclosure in accordance with at least one embodiment.

FIG. 78 is a rear perspective view of tablet enclosure in accordance with at least one embodiment.

FIG. 79 is a flow diagram of a method to provide a tablet enclosure in accordance with at least one embodiment.

FIG. 80 is a rear view of a tablet enclosure in accordance with at least one embodiment.

The use of the same reference symbols in different drawings indicates similar or identical items.

### DETAILED DESCRIPTION OF THE INVENTION

An enclosure for tablet and other electronic devices is described, with features to provide secure mounting options. In one or more embodiments, the enclosure provides options for mounting to a variety of supports, including a desktop stand, VESA compliant mounts and electrical wall boxes. Security options include the ability to secure the tablet device inside the enclosure to provide a deterrent to theft or vandalism. Additional levels of security may be provided that limit access to the tablet device's control features (i.e., control buttons, cameras, sensors, touchscreens) to prevent unauthorized or accidental activation of these features.

In accordance with at least one embodiment, the apparatus of the invention comprises an enclosure for tablet devices. In accordance with at least one embodiment, the enclosure comprises a faceplate, a retainer, and a rear housing. In accordance with at least one embodiment, the rear housing is configured with a plurality of fastener receiving patterns for mounting to a variety of fixtures. In accordance with at least one embodiment, the apparatus comprises a stand coupled to the enclosure by a hinge mechanism. In accordance with at least one embodiment, the stand reclinably orients the enclosure for compatibility with an orientation of the surface.

In accordance with at least one embodiment, the rear housing is configured with a fastener receiving pattern that is compatible with a Video Electronics Standards Association (VESA) standard mounting pattern to allow VESA-compliant mounts to be attached to the enclo sure.

In accordance with at least one embodiment, the apparatus comprises a stamped metal retainer and tamper-resistant screws. The stamped metal retainer includes screw holes. The tamper-resistant screws are insertable through the screw holes to affix the stamped metal retainer to the rear housing for providing secure retention of a tablet device in the enclosure.

In accordance with at least one embodiment, the screw holes are disposed around a periphery of a display area. In accordance with at least one embodiment, the apparatus further comprises a reinforcing mounting plate. In one or more embodiments, the plate comprises a substantially planar portion, a side portion disposed about a periphery of the substantially planar portion, and a fixture portion disposed about a periphery of the side portion. The plate defines a size and a depth of a tablet device volume. The plate is disposable between the tablet device and the rear housing.

In accordance with at least one embodiment, the enclosure of the invention comprises a rear housing defining a tablet device usable volume, a faceplate cooperative with the rear housing for defining the tablet device usable volume, and a reinforcement disposable between the tablet device usable volume and the rear housing. The reinforcement is configured to selectably engage a mating portion selected from a group including, for example, a Video Electronics Standards Association (VESA) standard mount, electrical wall boxes, and a stand comprising a hinge mount. In accordance with at least one embodiment, the rear housing includes holes located to be compatible with the VESA standard mount and the reinforcement includes threaded receptacles located to be compatible with the VESA standard mount.

In accordance with at least one embodiment, a tablet enclosure comprises a control linkage allowing activation of a control feature of a tablet device from an exterior of the enclo sure.

In accordance with at least one embodiment, an orientation-reversing connector adapter is disposed within the tablet device usable volume. In accordance with at least one embodiment, the orientation-reversing connector adapter comprises a rigid printed circuit board (PCB). In accordance with at least one embodiment, the orientation-reversing docking connector adapter comprises a flexible printed circuit (FPC).

In accordance with at least one embodiment, a method for securing a tablet device comprises coupling an orientation-reversing connector adapter to a tablet device, coupling a cable to the orientation-reversing connector adapter, routing the cable through a rear housing, installing the tablet device into the rear housing, affixing a faceplate to the rear housing, and affixing the rear housing to a fixture so as to transform the tablet device from being a portable machine to being a fixed machine. In accordance with at least one embodiment, the method further comprises fastening a stamped metal retainer to the rear housing tamper-resistant screws. The tablet device is contained between the stamped metal retainer and the rear housing.

In accordance with at least one embodiment, the method further comprises inserting a reinforcing plate between the tablet device and the rear housing. In accordance with at least one embodiment, the method further comprises installing a stand on the rear housing, the stand pivotably coupled to the rear housing. In accordance with at least one embodiment, the method further comprises providing a control linkage between a control feature of the tablet device and an externally accessible button of the rear housing.

Various exemplary embodiments of apparatus illustrated in the accompanying drawings are shown to accommodate a tablet device, such as, for example, an IPAD (trademark of Apple, Inc.) tablet. However, the invention is applicable to other tablet products and/or other electronic devices. Any references to IPAD include but are not limited to the IPAD2 and subsequent released IPAD models.

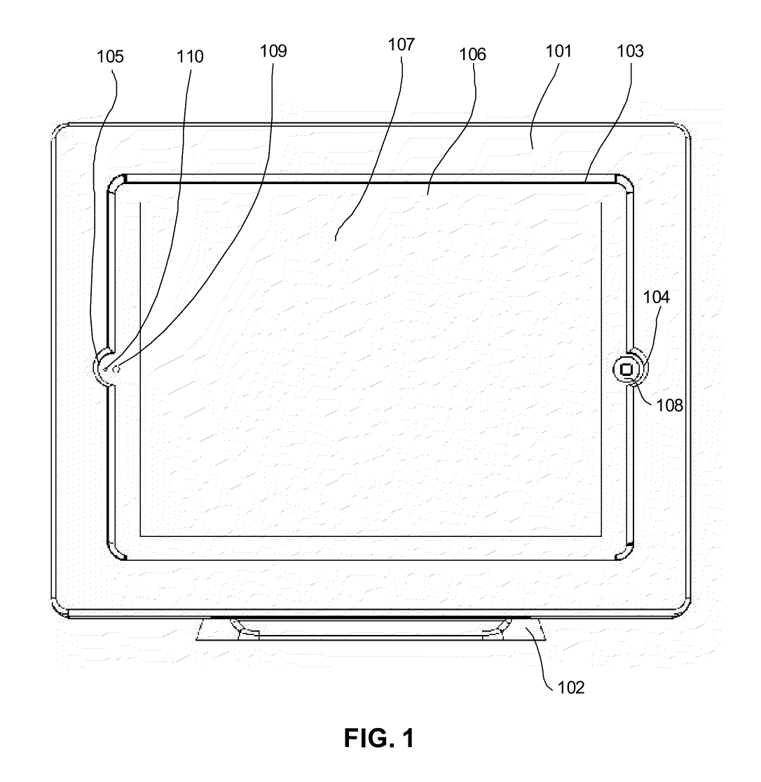

FIGS. 1 to 8 show an embodiment of the enclosure of the invention configured as a desktop stand. In this configuration the tablet device is mounted inside the enclosure. Depending on the specific embodiment, access to one or more tablet device features is accommodated or restricted.

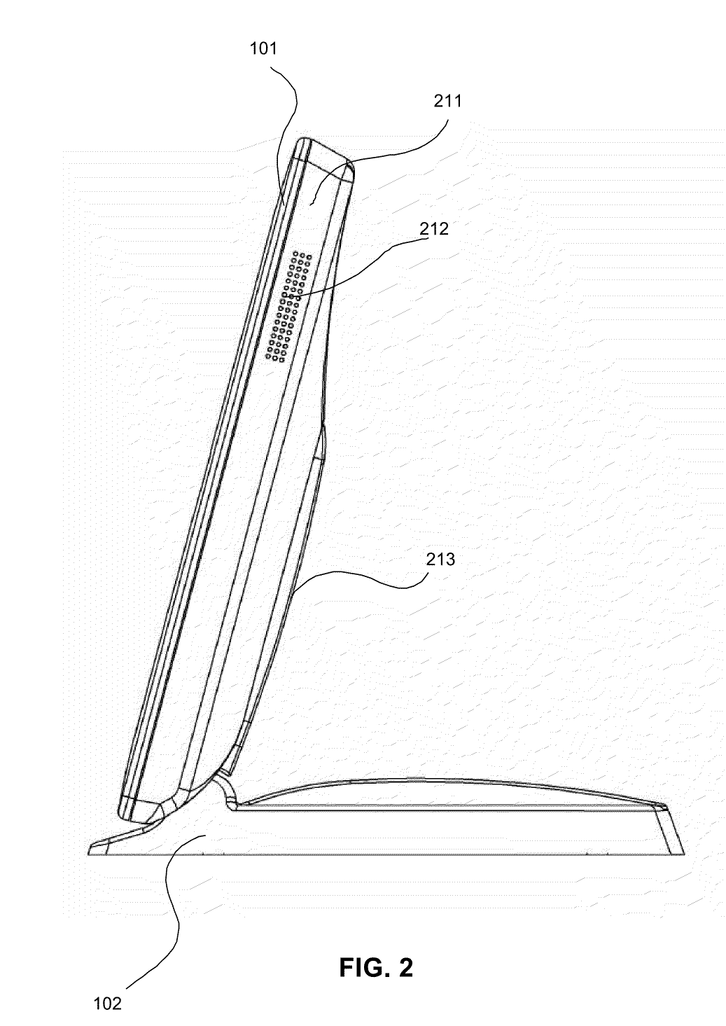

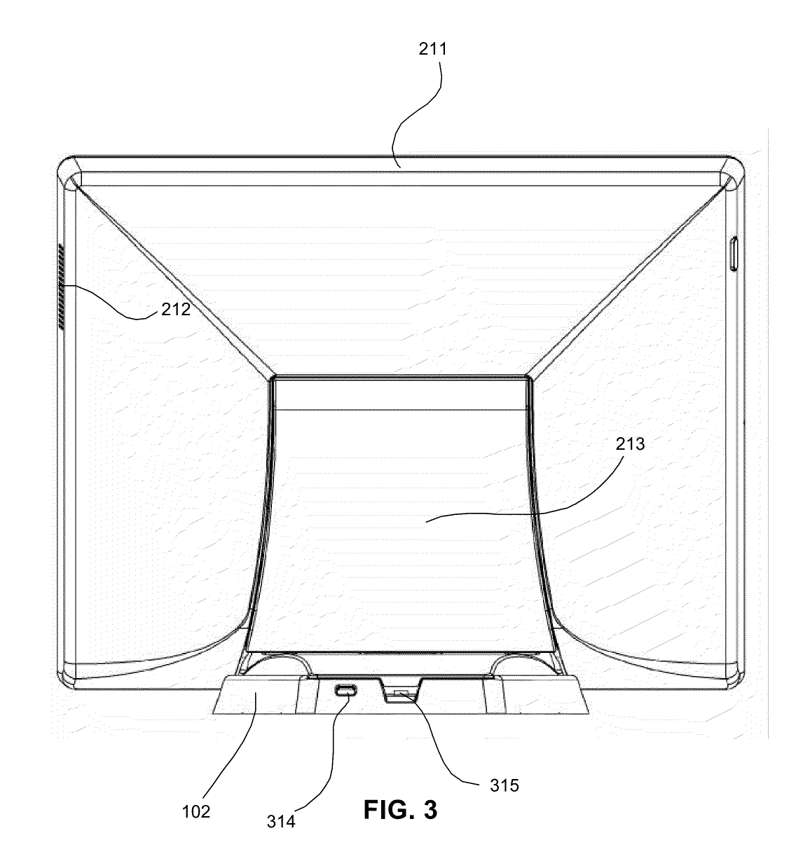

FIG. 1 is a front view of a tablet enclosure and stand in accordance with an exemplary embodiment. The tablet enclosure and stand of FIG. 1 comprises faceplate 101 and stand 102. Faceplate 101 is coupled to a rear housing (depicted in subsequent drawings, e.g. FIGS. 2 and 3). Faceplate 101 includes an aperture 103 through which a display 107 and, in accordance with at least one embodiment, at least a portion of a face 106 of a tablet device are visible. In accordance with at least one embodiment, an indentation 104 is provided in faceplate 101 to allow access to a button 108 of the tablet device. In accordance with at least one embodiment, an indentation 105 is provided in faceplate 101 to allow access to at least one of a camera 109 and a proximity sensor 110. As shown in FIG. 1 the front cover of the enclosure provides access to the tablet's home button, camera, and motion sensor.

FIG. 2 is a side view of a tablet enclosure and stand in accordance with an exemplary embodiment. The tablet enclosure and stand of FIG. 2 comprises faceplate 101, rear housing 211, panel 213, and stand 102. Faceplate 101 is coupled to rear housing 211. Rear housing 211 is coupled to stand 102. In accordance with at least one embodiment, rear housing 211 is coupled to stand 102 via a hinge, allowing adjustment of the position of the tablet enclosure relative to stand 102. In accordance with at least one embodiment, rear housing 211 includes a speaker grille 212 defining at least one aperture to allow transmission of sound through rear housing 211. In accordance with at least one embodiment, panel 213 is coupled to and covers at least a portion of rear housing 211.

FIG. 3 is a rear view of a tablet enclosure and stand in accordance with an exemplary embodiment. The stand 102 of FIG. 3 includes a slot 314 and an indentation 315. In accordance with at least one embodiment, slot 314 is compatible with security devices made by various manufacturers, such as KENSINGTON, for physically securing computing equipment. In accordance with at least one embodiment, indentation 315 provides at least one of access to a connector and clearance for routing cabling for connection of the tablet device to external devices.

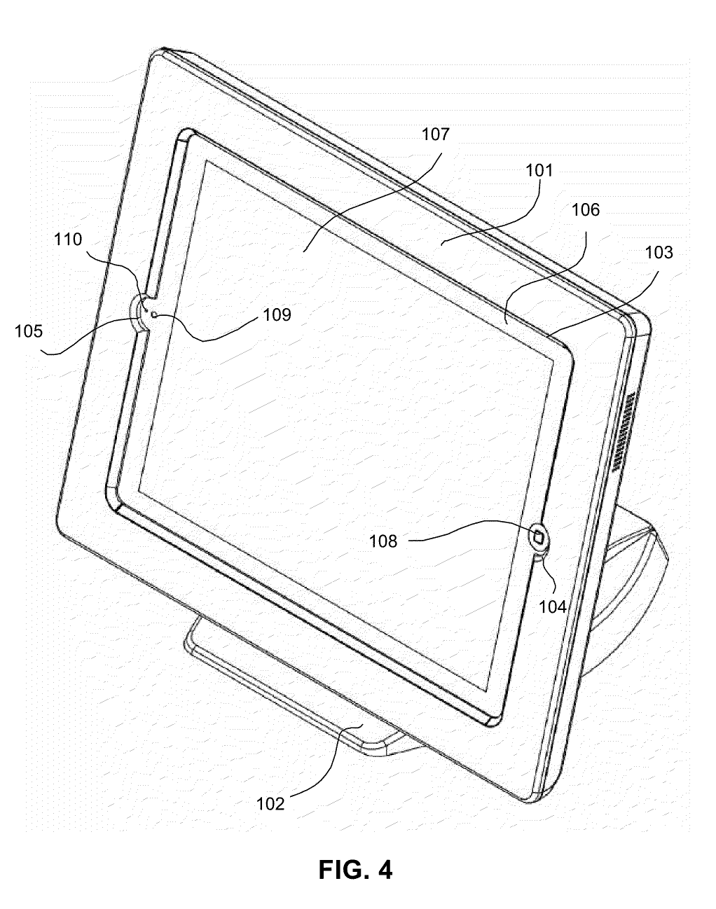

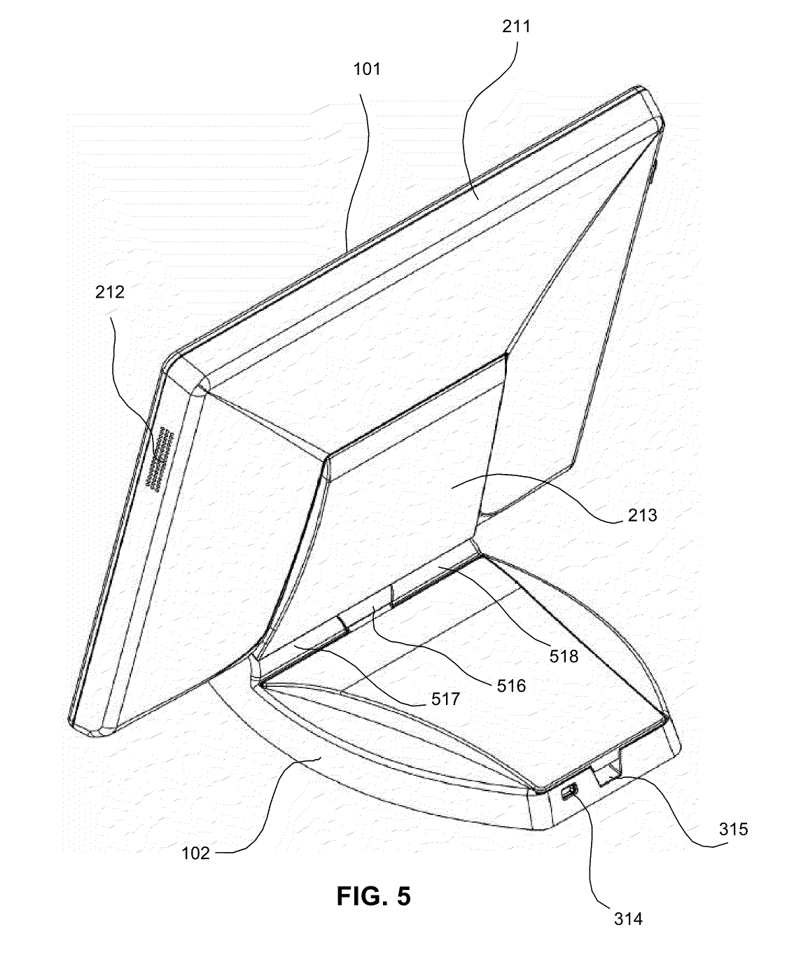

FIG. 4 is a front perspective view of a tablet enclosure and stand in accordance with an exemplary embodiment. FIG. 5 is a rear perspective view of a tablet enclosure and stand in accordance with an exemplary embodiment. In accordance with at least one embodiment, a hinge between rear housing 211 and stand 102 is provided, wherein rear housing 211 comprises hinge portion 516 and wherein stand 102 comprises hinge portions 517 and 518. In accordance with at least one embodiment, hinge portions 516, 517, and 518 are disposed so as to rotate about a common axis. FIGS. 4 and 5 show the unit with the display assembly rotated to an angle of approximately 75 degrees.

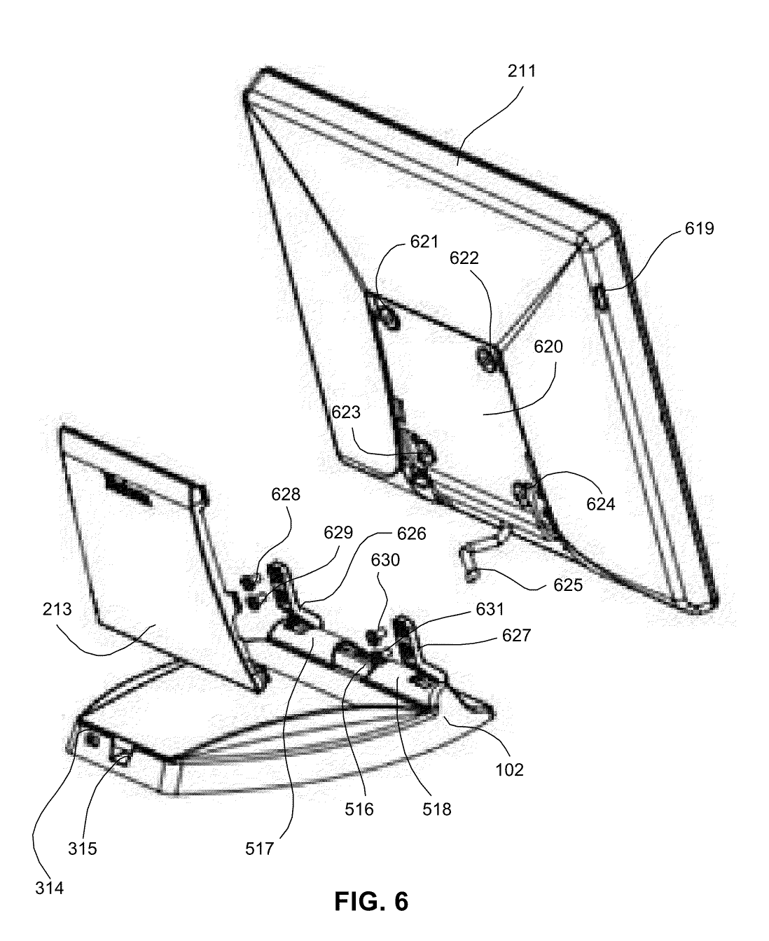

FIG. 6 is an exploded perspective view of a tablet enclosure and stand in accordance with an exemplary embodiment. In one or more embodiments, tamperproof screws are used to attach the enclosure to the stand, such as, for example spanner head (SNAKE EYES) screws. Other styles of tamperproof screws can be used in place of the spanner head screws to act as a deterrent to removing the tablet enclosure from the stand.

In the embodiment of FIG. 6, the stand contains hinges that serve as the attachment points to the tablet enclosure. The hinges allow the tablet enclosure to rotate and tilt to provide optimal viewing angles for the user. The tablet enclosure may be further secured with an internal security strap or cable that connects to the metal rear mount stamping in the upper assembly that passes through the hinge area and through the base and is permanently affixed to a mounting surface.

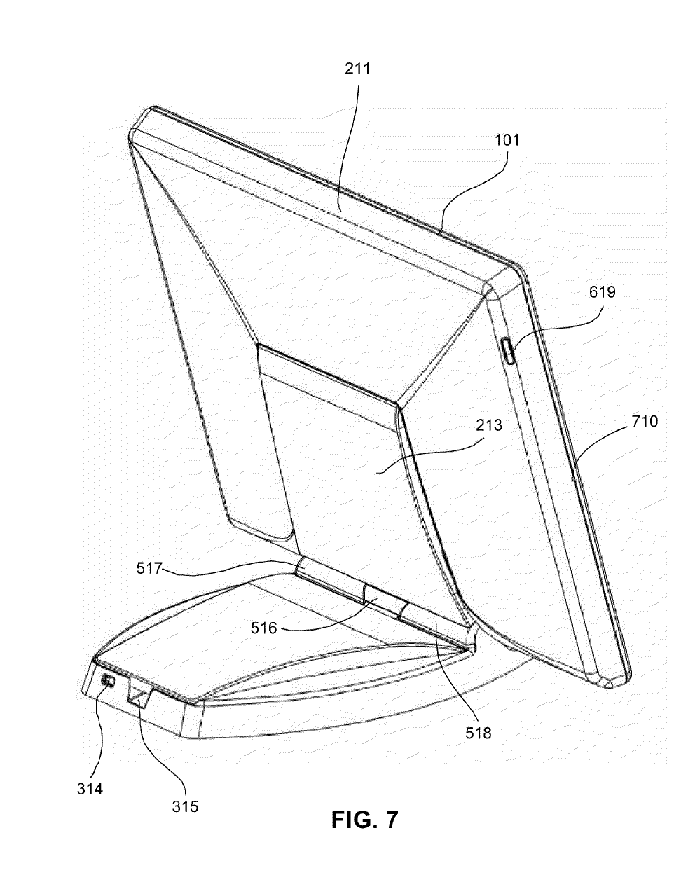

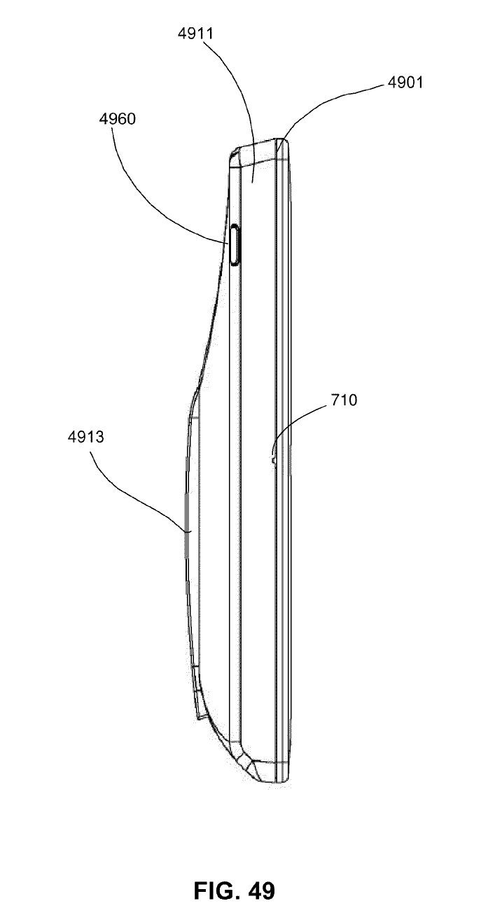

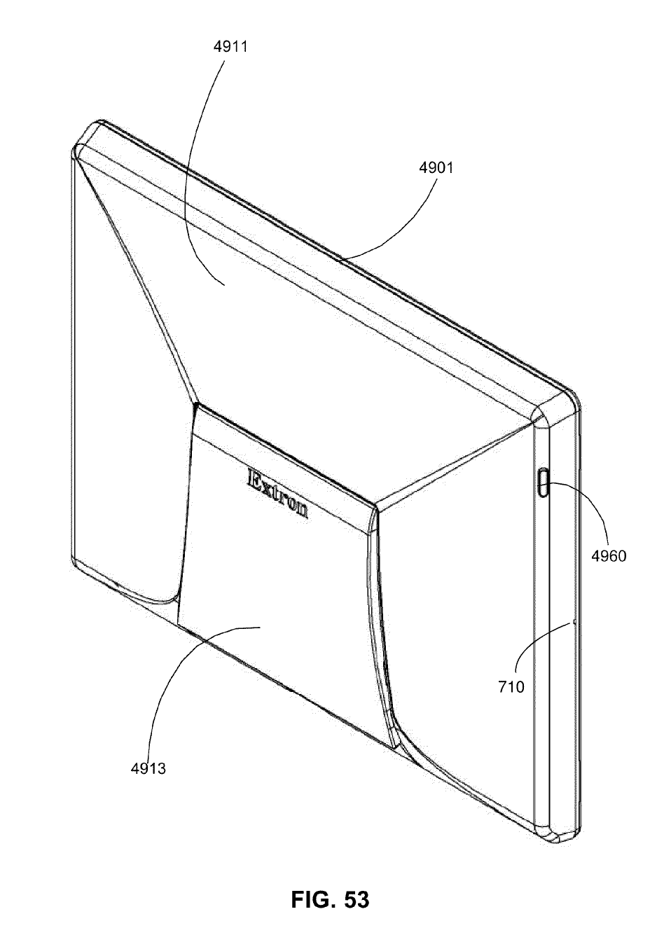

FIG. 7 is a perspective view of a tablet enclosure and stand in accordance with an exemplary embodiment. The embodiment of FIG. 7 comprises a button 619. Button 619 aligns to a control button of the tablet device (such as, for example, a “Sleep/Wake” button of an IPAD tablet) and activates the button when actuated. The embodiment of FIG. 7 also includes an orifice 710 (also shown in FIGS. 49 and 53) that is disposed adjacent to a microphone of the tablet device and provides a passage for external sounds to reach the microphone of the table device.

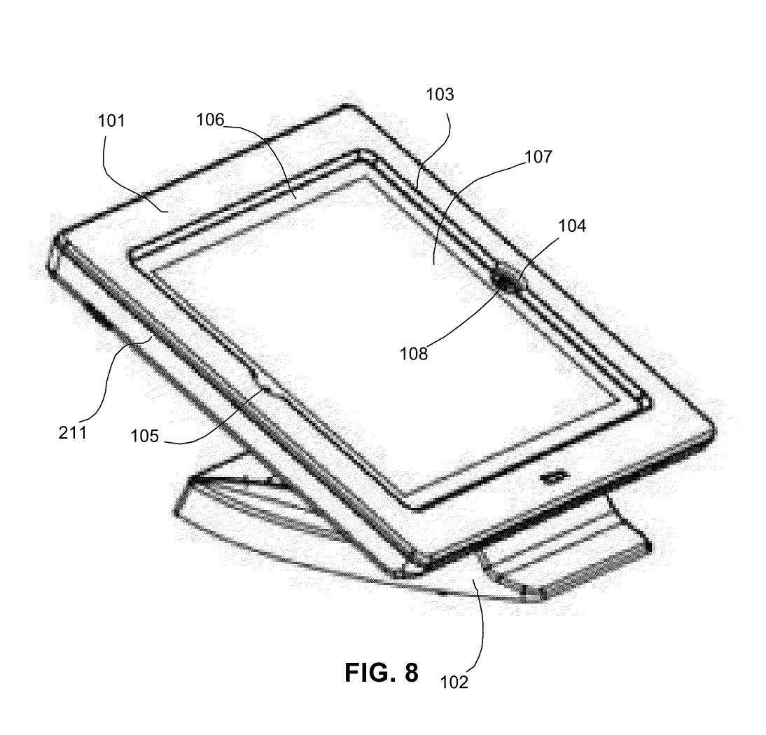

FIG. 8 is a perspective view of a tablet enclosure and stand in accordance with an exemplary embodiment enclosing a tablet device depicting the tablet device in an inclined position. FIG. 8 shows the unit rotated to an angle of approximately 30 degrees.

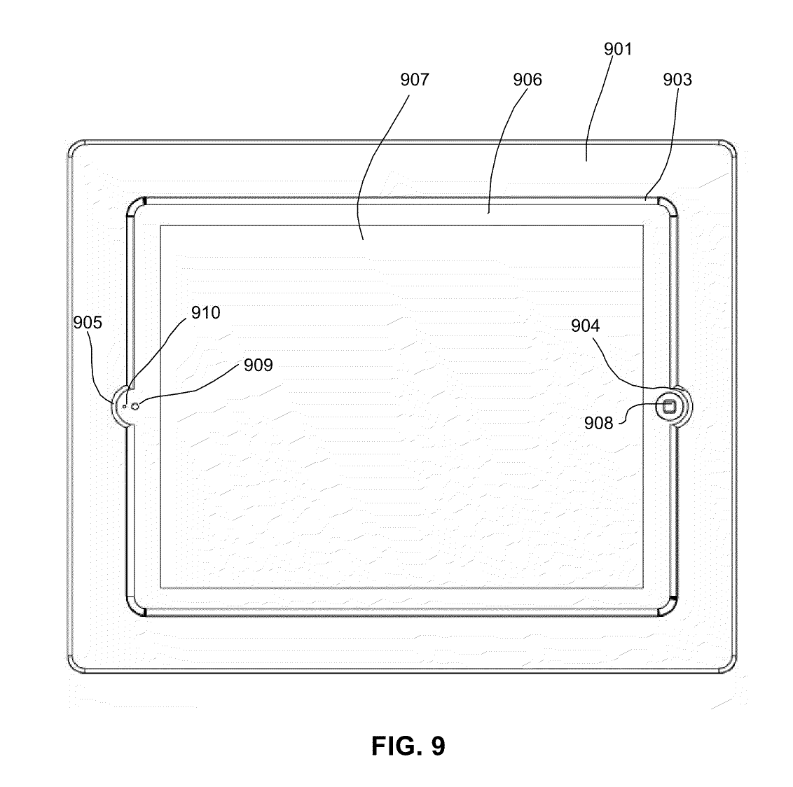

FIG. 9 is a front view of a tablet enclosure in accordance with an exemplary embodiment. The tablet enclosure of FIG. 9 comprises faceplate 901 behind which a tablet comprising face 906, display 907, button 908, camera 909, and/or proximity sensor 910 is disposed. In accordance with at least one embodiment, indentation 904 is included in faceplate 901 to allow access to button 908. In accordance with at least one embodiment, indentation 905 is included in faceplate 901 to allow access to camera 909 and/or proximity sensor 910.

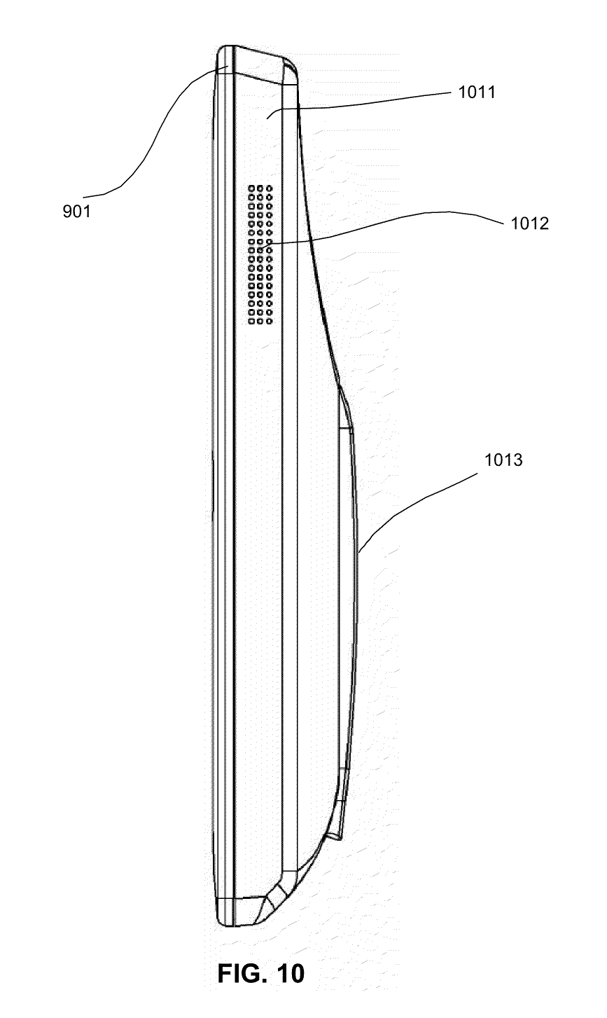

FIG. 10 is a side view of a tablet enclosure in accordance with an exemplary embodiment. The tablet enclosure of FIG. 10 comprises faceplate 901, rear housing 1011, and panel 1013. Faceplate 901 is coupled to rear housing 1011, which is coupled to panel 1013. In accordance with at least one embodiment, speaker grille 1012 is included in rear housing 1011.

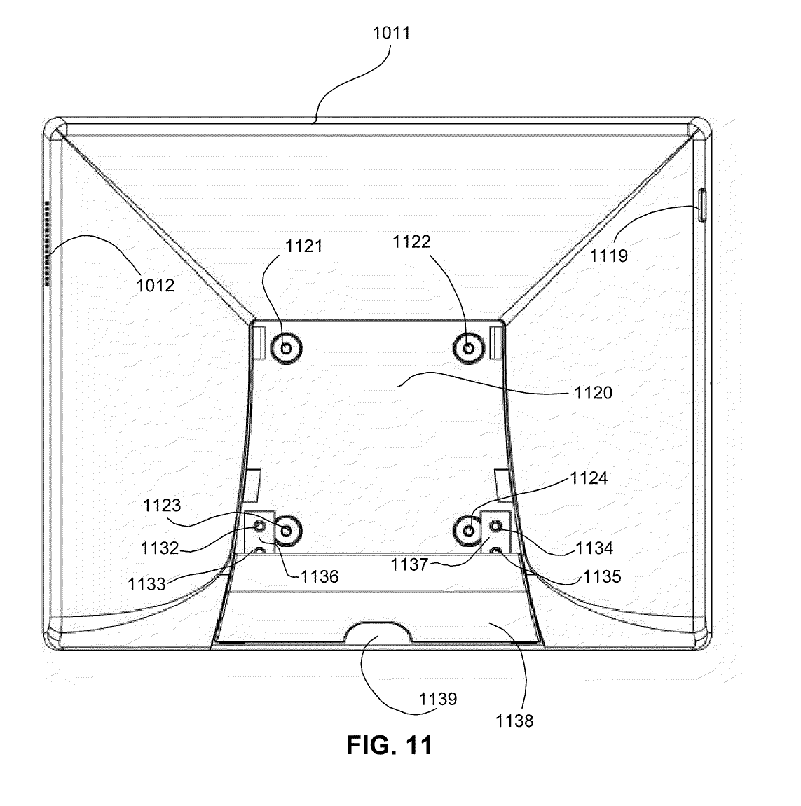

FIG. 11 is a rear view of a tablet enclosure in accordance with an exemplary embodiment. The tablet enclosure of FIG. 11 comprises rear enclosure 1011, panel 1138, and button 1119. In accordance with at least one embodiment, rear housing 1011 includes speaker grille 1012. In accordance with at least one embodiment, rear housing 1011 includes a plate 1120, which includes holes 1121, 1122, 1123, and 1124. In accordance with at least one embodiment, at least a portion of plate 1120 may be covered by panel 1013, if panel 1013 is installed. In accordance with at least one embodiment, rear housing 1011 includes hinge mounts 1136 and 1137. In accordance with at least one embodiment, hinge mount 1136 includes holes 1132 and 1133. In accordance with at least one embodiment, hinge mount 1137 includes holes 1134 and 1135. In accordance with at least one embodiment, panel 1138 is coupled to rear housing 1011. In accordance with at least one embodiment, as shown if FIG. 11, panel 1138 snaps onto the back of the rear housing to enclose the hinge area and provide a clean look to the product. In accordance with at least one embodiment, panel 1138 includes indentation 1139 through which cables may be routed.

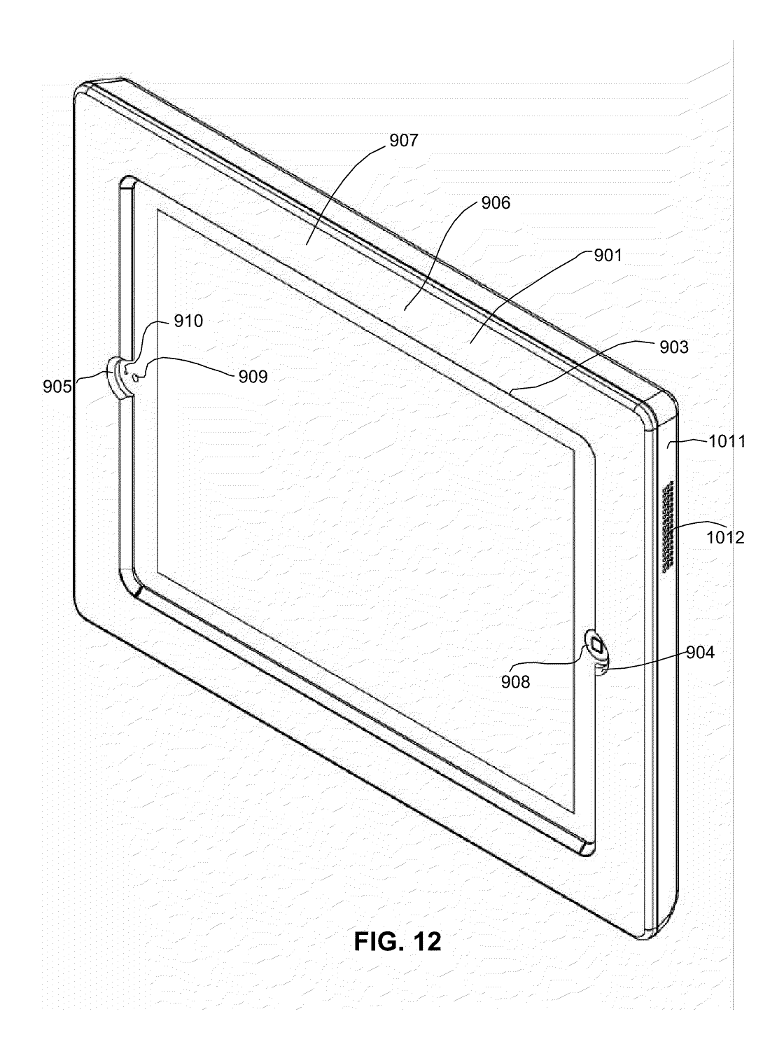

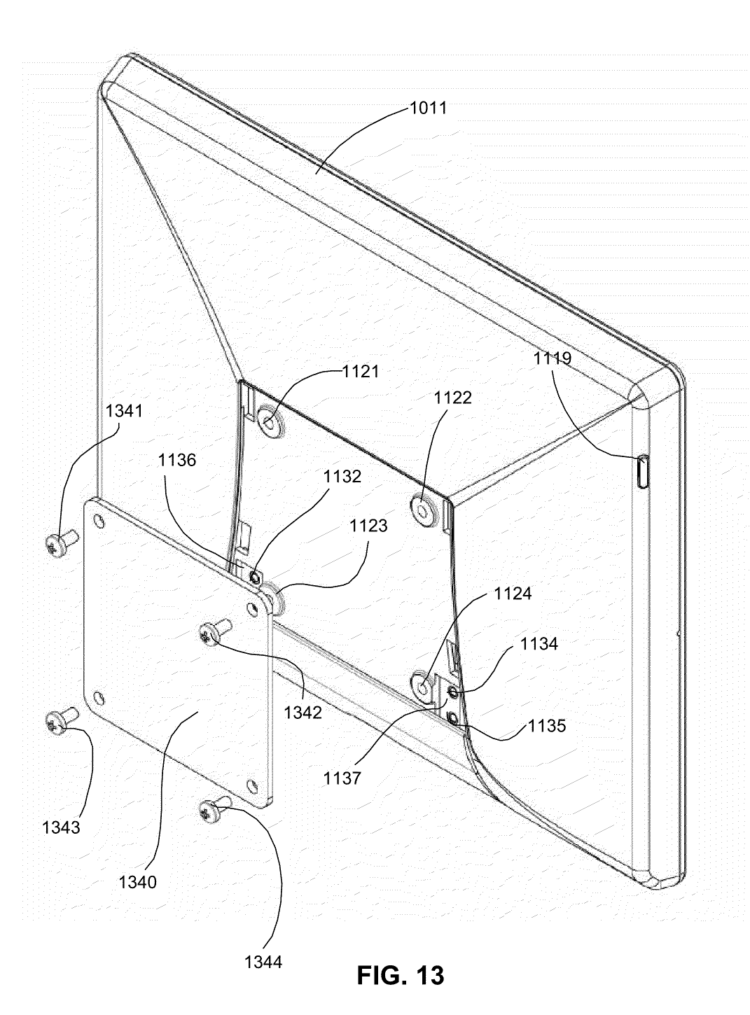

FIG. 12 is a front perspective view of a tablet enclosure in accordance with an exemplary embodiment. FIG. 13 is a rear perspective view of a tablet enclosure in accordance with an exemplary embodiment. In accordance with at least one embodiment, holes 1121, 1122, 1123, and 1124 are included in rear housing 1011 to be compatible with a standard Video Electronics Standards Association VESA MIS-D75 mount. In accordance with at least one embodiment, a plate 1340 (which may be part of a VESA mount) is attached to rear housing 1011 using screws 1341, 1342, 1343, and 1344 that pass through holes 1121, 1122, 1123, and 1124, respectively. In accordance with at least one embodiment, screws 1341, 1342, 1343, and 1344 engage female threads which may be implemented, for example, as molded portions of rear housing 1011 or, for example, as threaded inserts coupled to rear housing 1011.

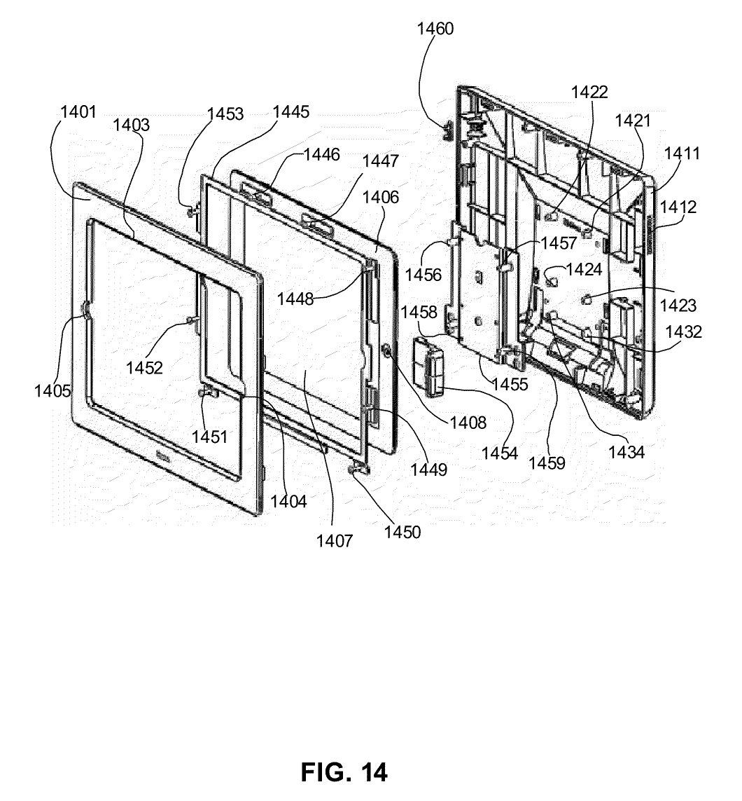

FIG. 14 shows an exploded view of how a tablet device mounts inside the enclosure in one or more embodiments of the invention. With the tablet device placed into the rear housing 1411, a stamped metal retainer 1445 is placed over the tablet device and is secured with eight tamperproof screws 1446-1453. By using tamperproof screws the level of security is increased because tamperproof screw head designs require special tools. Screws such as TORX with pin, SNAKE EYES spanner head, anti-reverse slot heads, or other screws with anti-theft, anti-removal features may be used.

In accordance with at least one embodiment, the tablet enclosure of FIG. 14 comprises faceplate 1401, stamped metal retainer 1445, reorienting connector assembly 1454, plate 1455, rear housing 1411, button 1460, screws 1446, 1447, 1448, 1449, 1450, 1451, 1452, 1453, and threaded receptacles 1456, 1457, 1458, and 1459. In accordance with at least one embodiment, an aperture 1403 is included in faceplate 1401 to allow access to display 1407 of the tablet device enclosed in the tablet enclosure. In accordance with at least one embodiment, at least a portion of face 1406 of the tablet device is visible through aperture 1403 of faceplate 1401 of the tablet enclosure. In accordance with at least one embodiment, indentation 1404 is included in faceplate 1401 to allow access to button 1408 of the tablet device. In accordance with at least one embodiment, indentation 1405 is provided in faceplate 1401 to allow access to, for example, a camera, a microphone, a button, and/or another input, output, or input/output device of the tablet device. In accordance with at least one embodiment, holes 1421, 1422, 1423, 1424, and/or holes 1432 and 1434 are included in rear housing 1411 to allow mounting of the tablet enclosure. In accordance with at least one embodiment, speaker grille 1412 is included in rear housing 1411 to allow sound from the tablet device to exit the tablet enclosure. In the embodiment of FIG. 14, a reorienting connector assembly 1454 connects to a docking connector of the tablet device, as further described below.

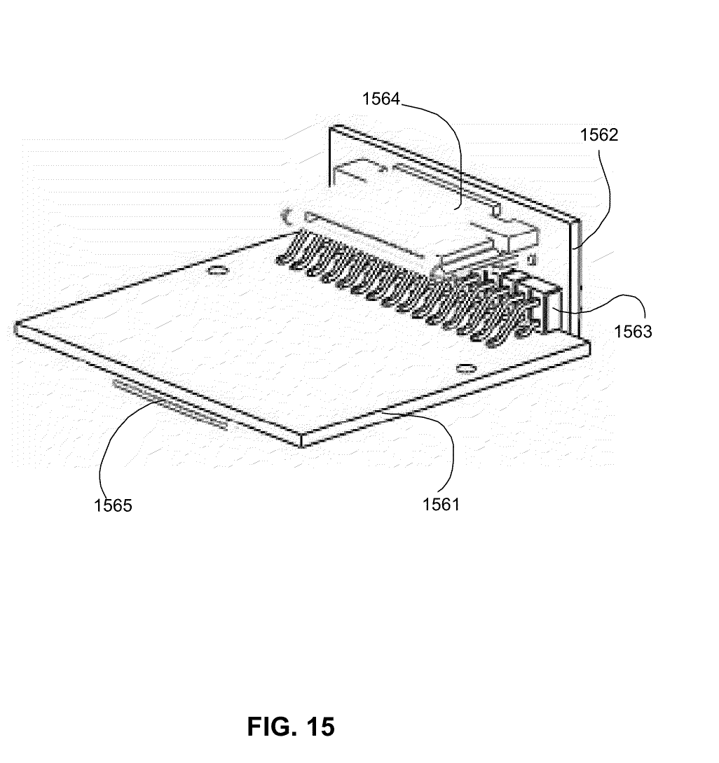

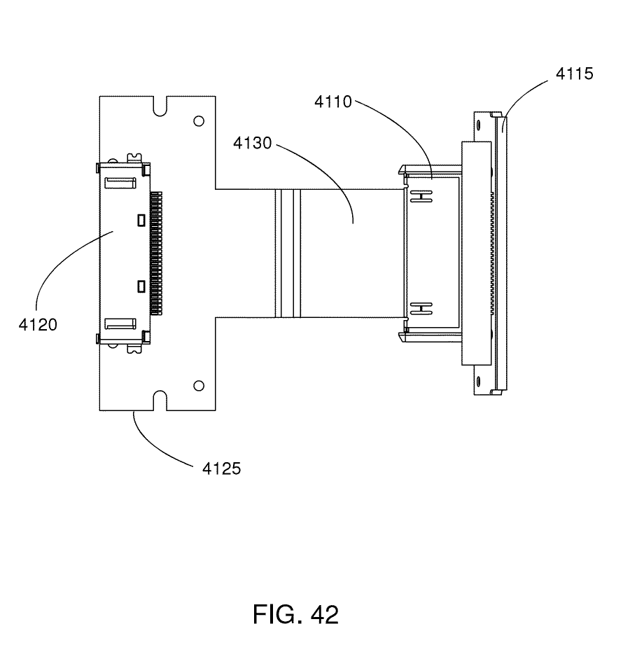

FIGS. 15 to 17, 40 to 42, and 57 to 61 show one or more embodiments of a reorienting electrical connector assembly of the invention. The reorienting electrical connector assembly of the invention allows a cable to be connected to a connector of the tablet device with minimal protrusion from the body of the tablet device and allows the cable to be enclosed in the enclosure without requiring the enclosure to be extended significantly beyond the periphery of the tablet device.

FIG. 15 is a perspective view of a reorienting electrical connector assembly in accordance with an exemplary embodiment. In accordance with at least one embodiment, the reorienting electrical connector assembly comprises printed circuit board (PCB) 1561, PCB 1562, header 1563, male connector 1564, and female connector 1565. In accordance with at least one embodiment, header 1563 electrically and mechanically connects PCB 1561 to PCB 1562. In accordance with at least one embodiment, header 1563 retains PCB 1561 at an angle, for example, a right angle, with respect to PCB 1562. In accordance with at least one embodiment, male connector 1564 is electrically and mechanically coupled to PCB 1562. In accordance with at least one embodiment, female connector 1565 is electrically and mechanically coupled to PCB 1561. In accordance with at least one embodiment, male connector 1564 is capable of coupling with a female docking connector of a tablet device. In accordance with at least one embodiment, female connector 1564 is capable of coupling with a male docking connector of a cable typically used to connect to a female docking connector of a tablet device. In accordance with at least one embodiment, the electrical connector assembly reorients an angle and position of the male docking connector of the cable with respect to the female docking connector of the tablet device to prevent the docking connector of the cable from protruding beyond the periphery of the tablet enclosure and instead orients the cable behind and towards the center of the tablet device within the tablet enclosure.

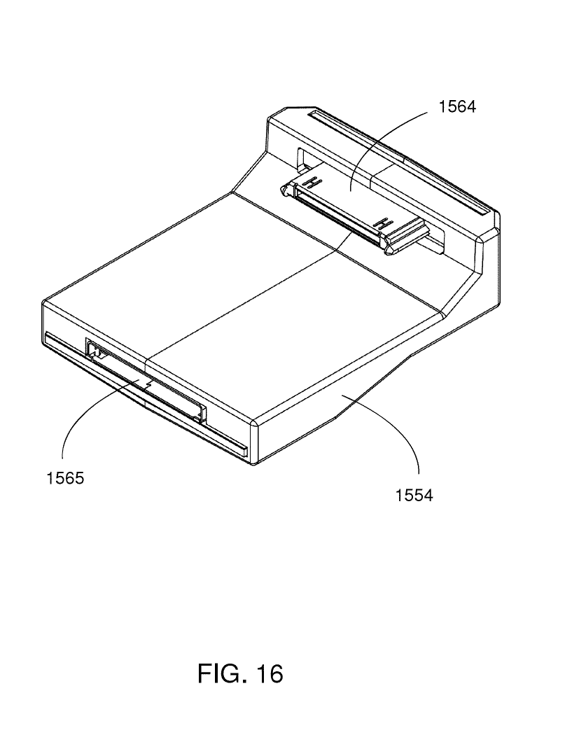

FIG. 16 is a perspective view of a reorienting electrical connector assembly in an electrical connector assembly housing in accordance with an exemplary embodiment. In accordance with at least one embodiment, electrical connector assembly housing 1654 encloses the electrical connector assembly of FIG. 15, allowing access to male connector 1564 and female connector 1565 through apertures included in electrical connector assembly housing 1654.

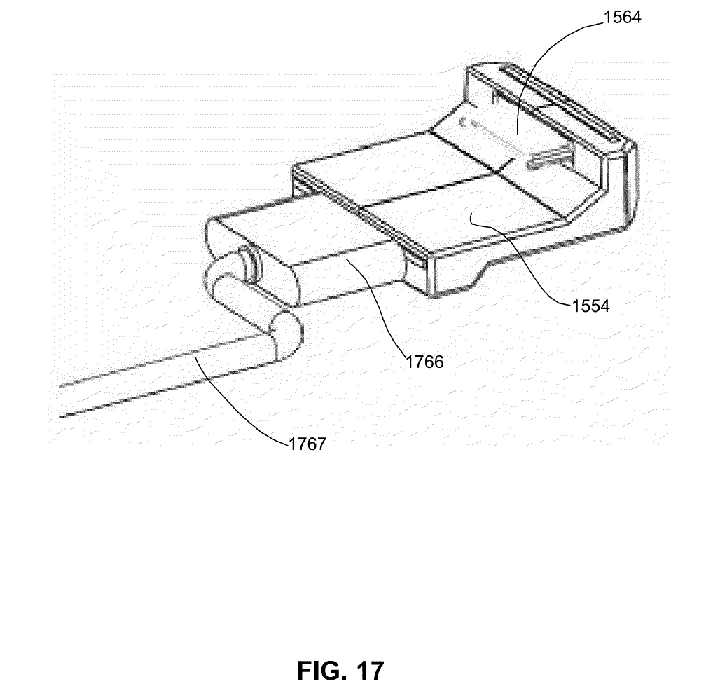

FIG. 17 is a perspective view of an electrical connector assembly in an electrical connector assembly housing in accordance with an exemplary embodiment connected to a cable. In accordance with at least one embodiment, cable 1767 is connected to male connector 1766 of the electrical connector assembly.

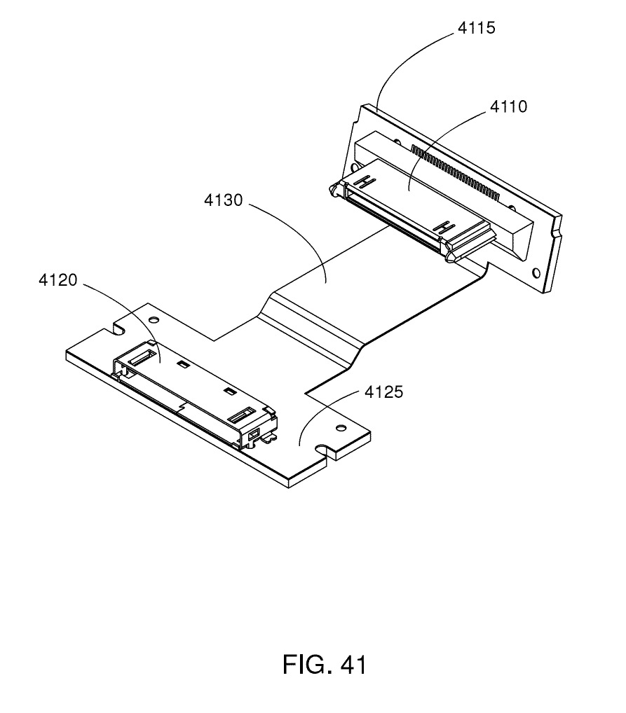

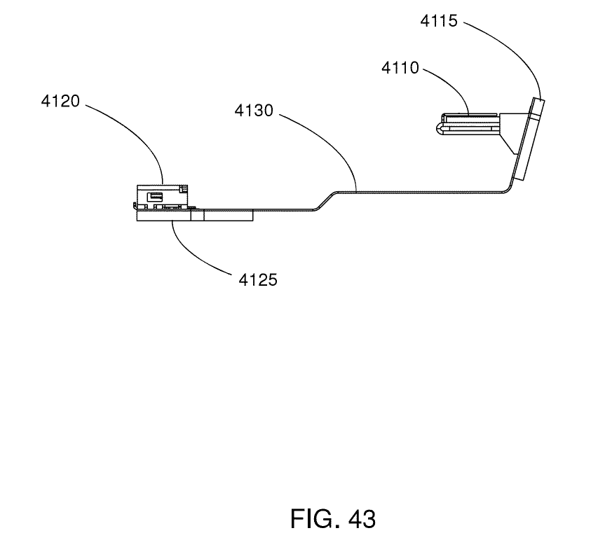

FIGS. 41 to 43 show perspective, top, and side views, respectively, of an embodiment of a reorienting electrical connector assembly in which connectors 4110 and 4120 are electrically coupled to a flexible printed circuit (FPC) 4130 that provides electrical connections between connectors 4110 and 4120 (which may, for example, be male and female docking connectors for a tablet device). Support boards 4115 and 4125, respectively, which may comprise PCB's, may be used to provide structural support and/or electrical connections to FPC 4130 and connectors 4110 and 4120. In one or more embodiments, the assembly is configured such that it can be mounted into a reorienting electrical connector assembly housing, such as, for example, housing 1554 of FIG. 16.

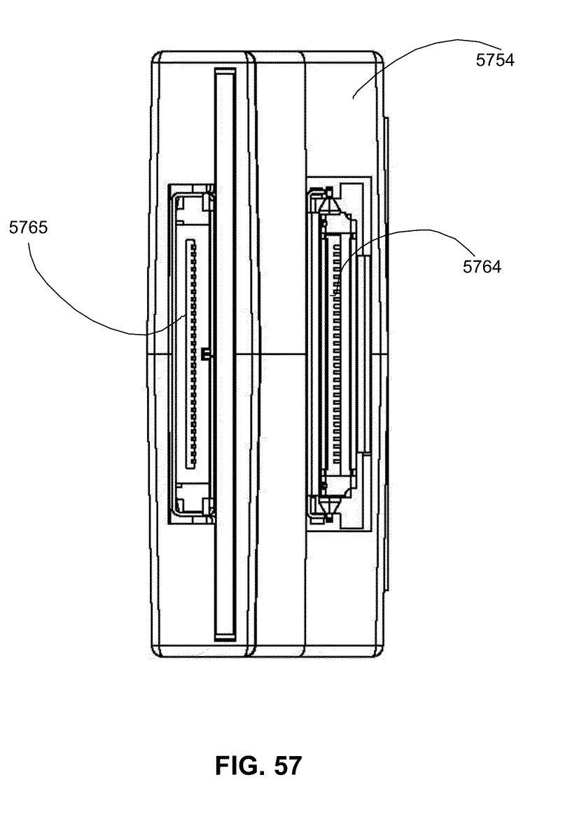

FIG. 57 is a front view of a reorienting connector assembly in accordance with at least one embodiment. In accordance with at least one embodiment, reorienting connector assembly comprises a housing 5754, a male connector 5764, and a female connector 5765. In one or more embodiments, a PCB provides continuity between signal lines of the male connector 5764 and the female connector 5765.

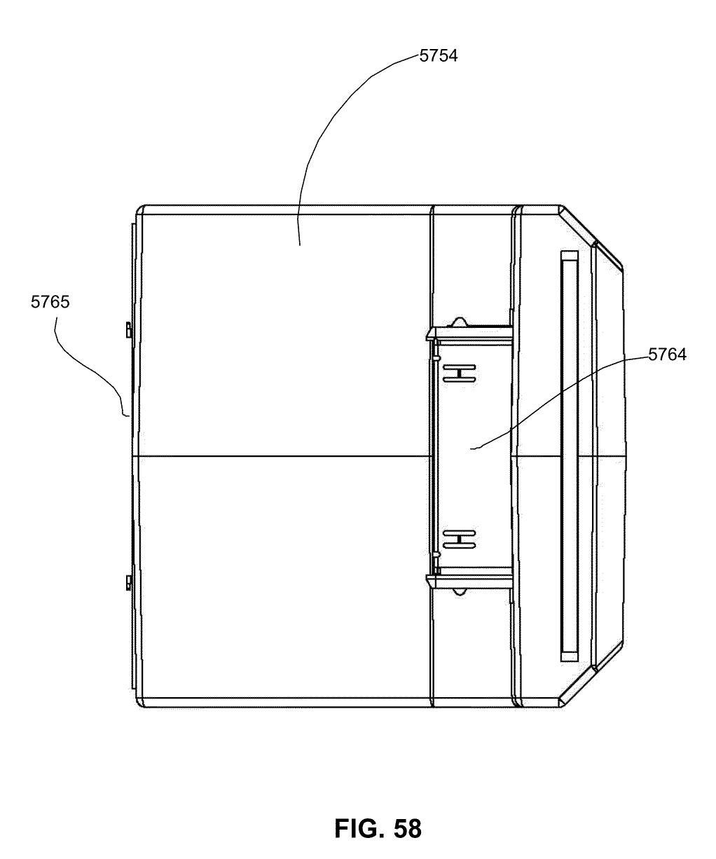

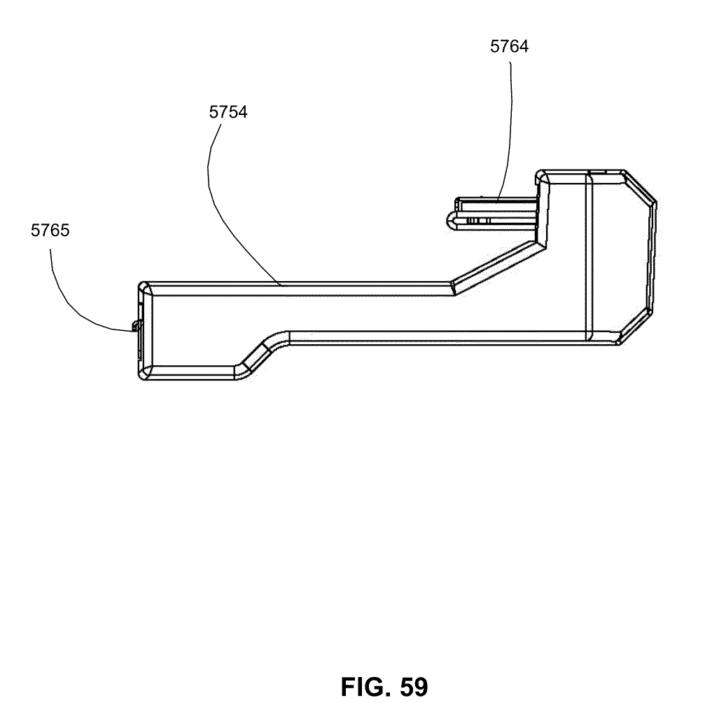

FIGS. 58 and 59 provide top and side views, respectively, of the reorienting connector assembly of FIG. 57.

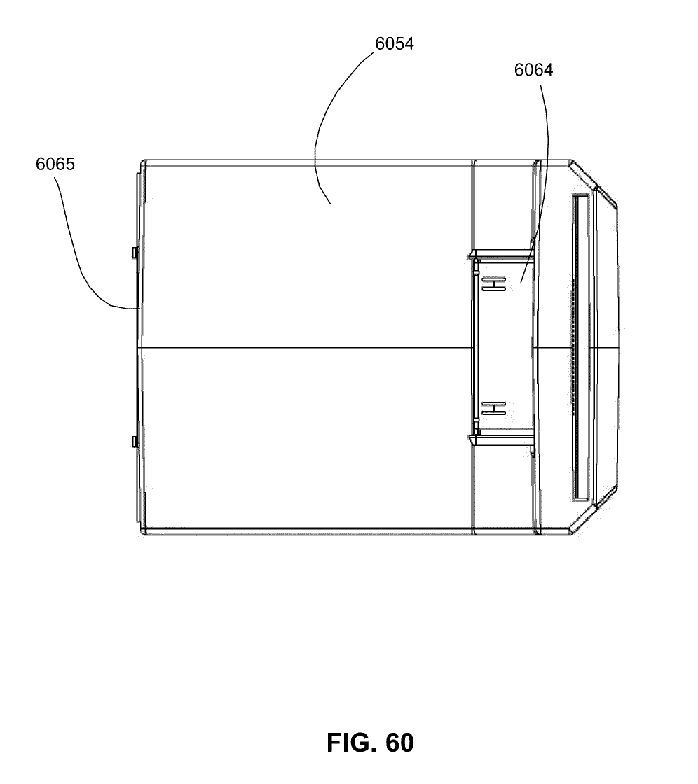

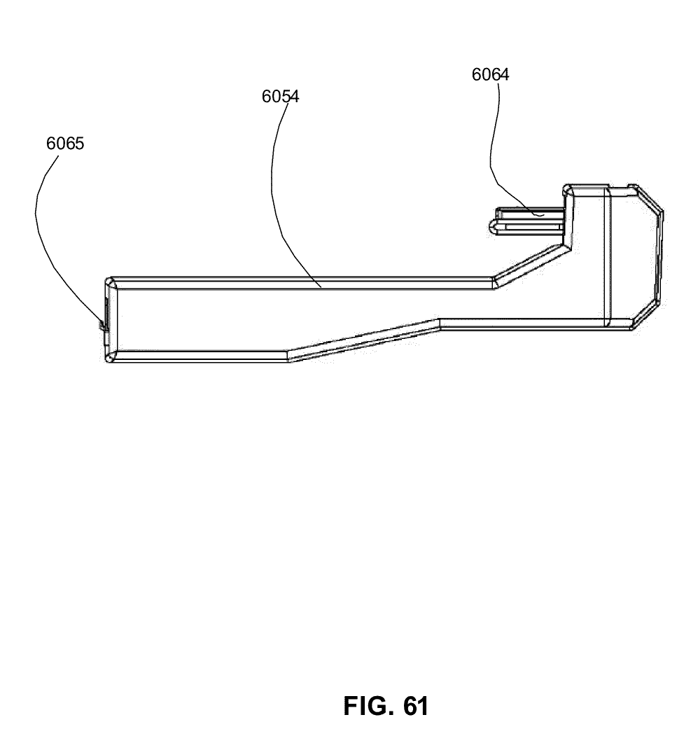

FIG. 60 is a top view of reorienting connector assembly in accordance with at least one embodiment. In accordance with at least one embodiment, the reorienting connector assembly comprises a housing 6054, a male connector 6064, and a female connector 6065. In one or more embodiments, a flexible printed circuit (FPC) provides continuity between signal lines of the male connector 6064 and the female connector 6065. FIG. 61 is a side view of the reorienting connector assembly of FIG. 60.

Although the reorienting connector assembly of the invention has been described with various combinations of male and female connectors, it will be apparent to those of skill in the art that the locations of the male and female connectors may be interchanged, that the connectors can be both male or both female, that more than two connectors may be provided, and that connectors of different types may be used, thereby providing adaptation as well as reorientation.

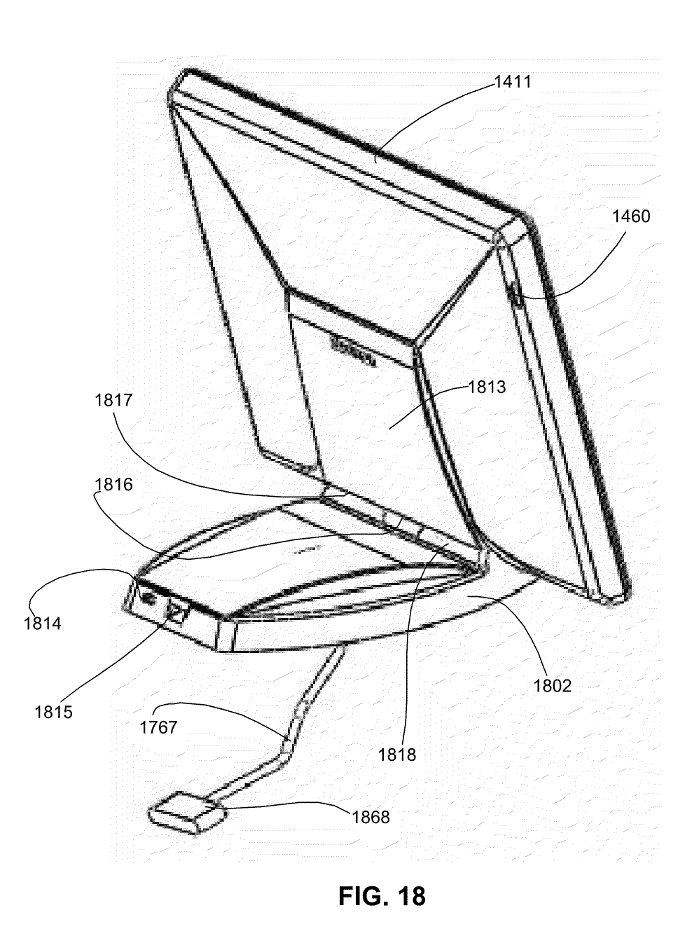

FIG. 18 is a rear perspective view of a tablet enclosure and stand in accordance with an exemplary embodiment enclosing a tablet device and comprising an electrical connector assembly and cable of FIG. 17, the electrical connector assembly being connected to the docking connector of the tablet device. In accordance with at least one embodiment, a slot 1814, for example, a security slot, is included in stand 1802. In accordance with at least one embodiment, an indentation 1815 is included in stand 1802 to allow passage of cable 1767 which has been reoriented by the reorienting electrical connector assembly of FIG. 17 inside the tablet enclosure towards the bottom center of rear housing 1411. In accordance with at least one embodiment, cable 1767 exits under stand 1802 and leads to a connector 1868. In accordance with at least one embodiment, hinge portion 1816 is coupled to rear housing 1411. In accordance with at least one embodiment, hinge portions 1817 and 1818 are rotatably coupled to hinge portion 1816 and are also coupled to stand 1802. Panel 1813 is coupled to rear housing 1411 to aesthetically cover a central portion of the rear of rear housing 1411.

In one or more embodiments, stand 1802 provides two exit points for cable 1767. FIG. 18 shows the cable existing out the bottom of stand 1802. This option may be preferred for installations where the stand is affixed to a table or where stand is configured to rotate. This installation method provides a clean installation where the cabling can be hidden. An alternative rear cable exit location 1815 is provided on stand 1802 to allow cable 1767 to pass though the rear of stand 1802.

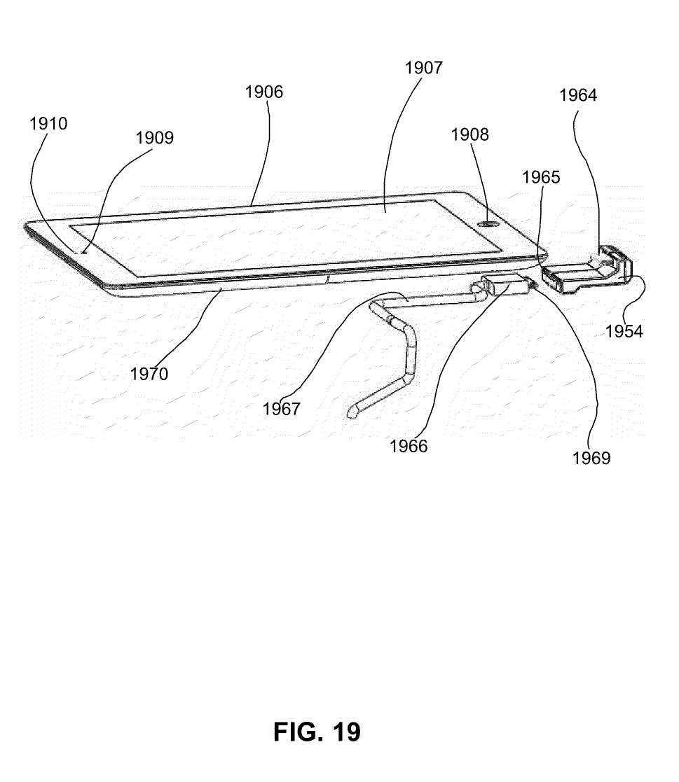

FIG. 19 is a cutaway view showing how a reorienting electrical connector assembly in accordance with an exemplary embodiment reorients an electrical cable 1967 in a tablet enclosure of the invention. In accordance with at least one embodiment, cable 1967 is coupled to connector 1966, which comprises male connector 1969, which is coupled to female connector 1965 of reorienting electrical connector assembly 1954. In accordance with at least one embodiment, female connector 1965 is coupled to male connector 1964 of reorienting connector assembly 1954. In the embodiment of FIG. 19, reorienting electrical connector assembly 1954 connects to the docking connector along the periphery of the tablet device adjacent to button 1908, and reorients cable 1967 inwards from the periphery of the tablet device.

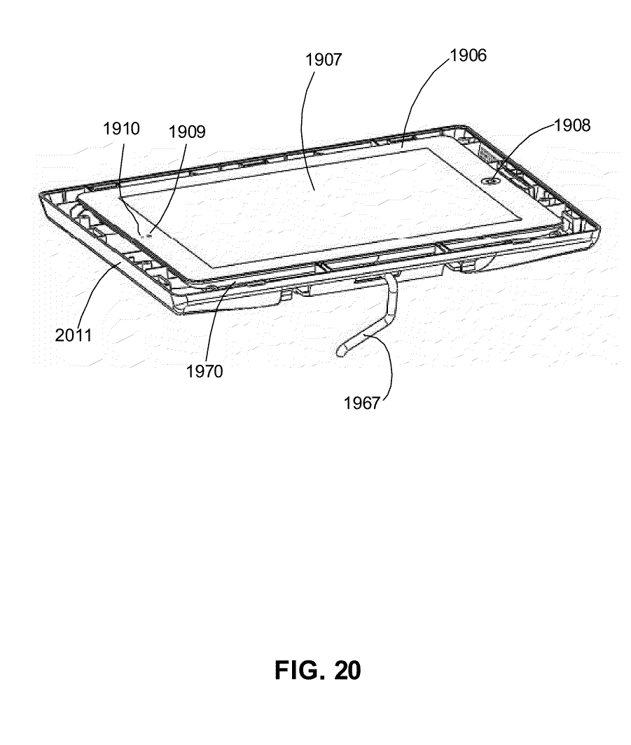

FIG. 20 is a perspective view of a rear housing 2011 of a tablet enclosure in accordance with an exemplary embodiment into which a tablet device is installed and an electrical connector assembly and cable are connected in the manner shown in FIG. 19. In accordance with at least one embodiment, rear housing 2011 of the tablet enclosure encloses rear housing 1970 of the tablet device.

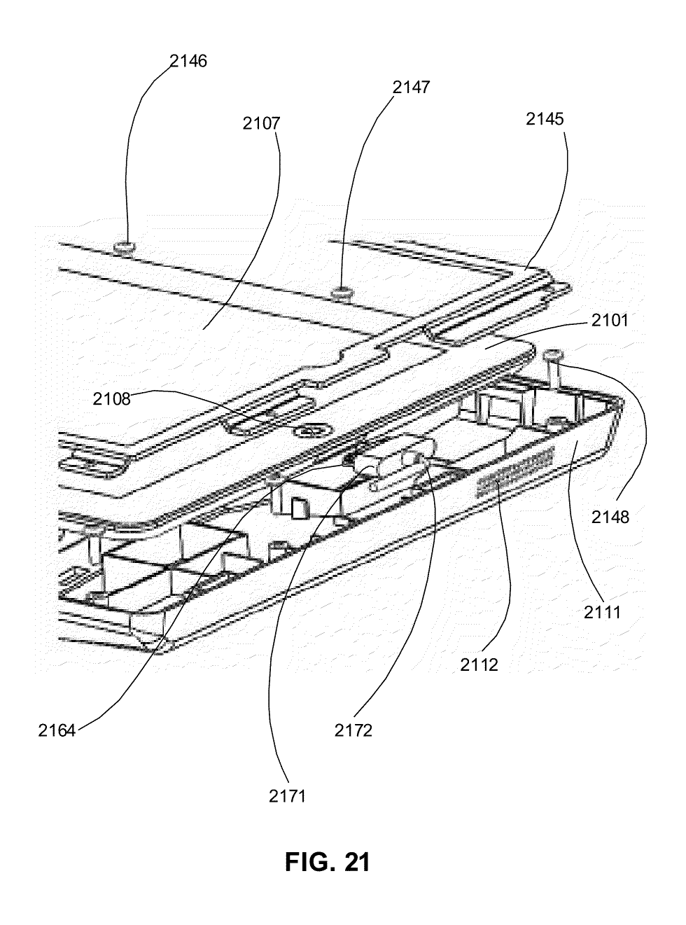

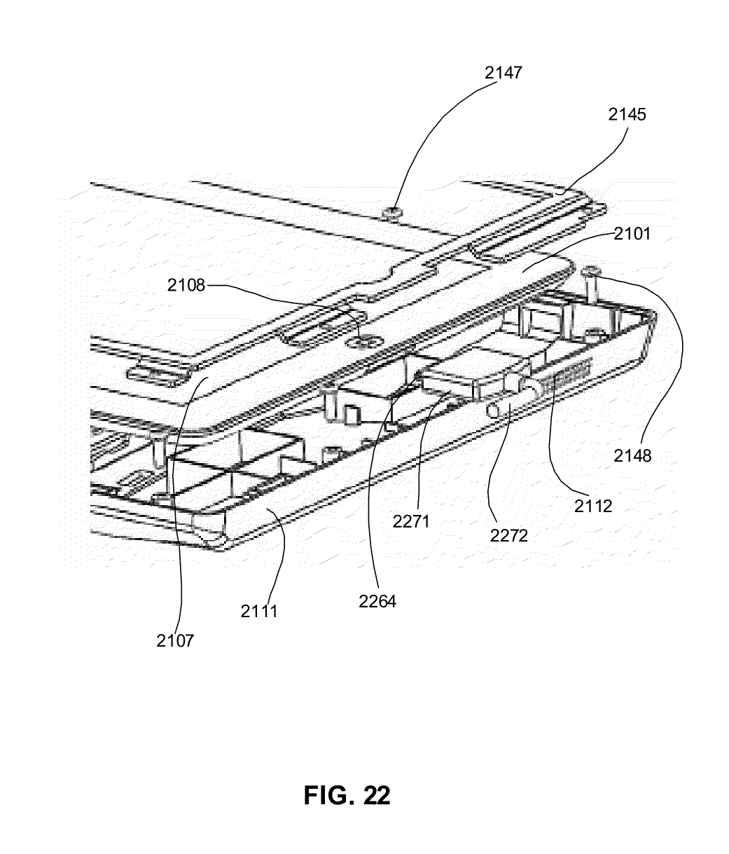

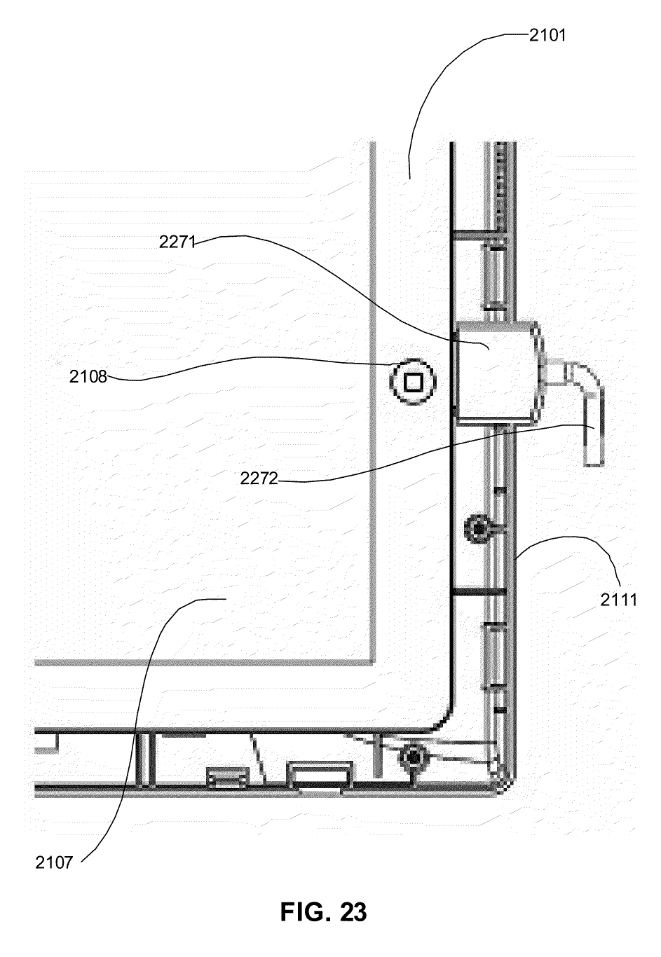

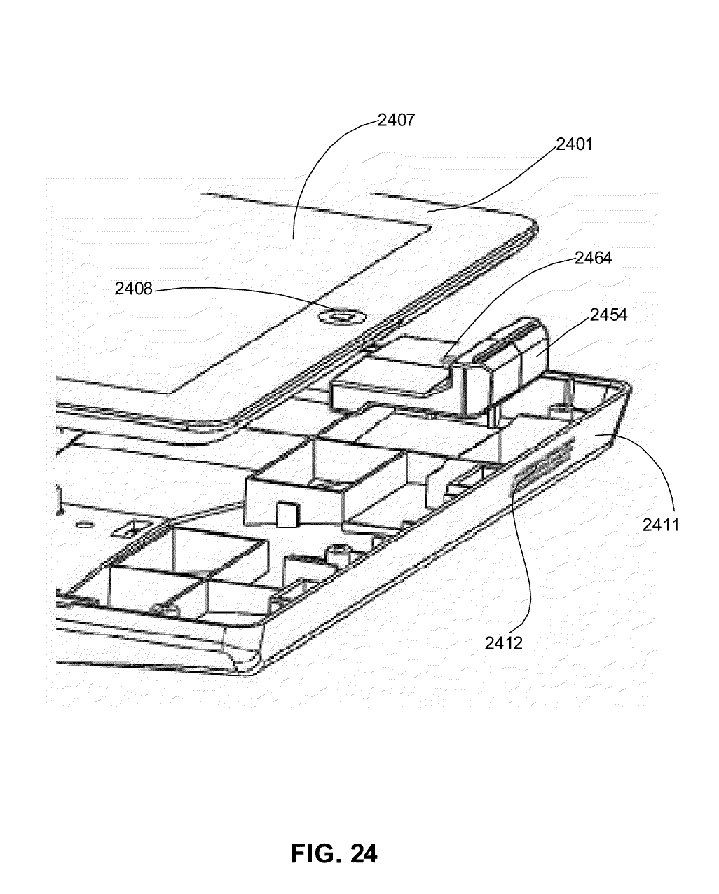

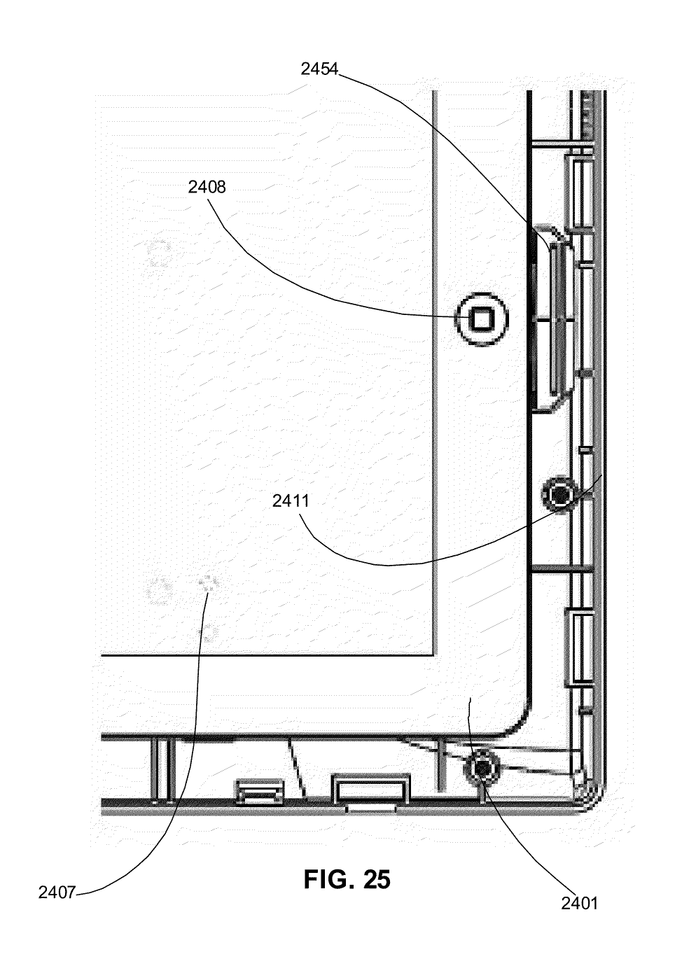

FIGS. 21-25 show the advantages of the reorienting electrical connector assembly of the invention. As shown in FIGS. 21-22, without the reorienting electrical connector assembly of the invention, conventional docking connectors 2171 and 2271 extend a significant amount beyond the periphery of the tablet device when connected to the device's docking connector. As shown in FIG. 23, the tablet enclosure would need to be extended to fully encompass docking connector 2271. As shown in FIGS. 24 and 25, use of reorienting connector assembly 2454 reorients the docking connector of the tablet device inwards and under the tablet device, allowing a docking cable connected to connector assembly 2454 to be enclosed within the tablet housing without requiring the housing to be extended significantly beyond the periphery of the tablet device.

As an illustrative embodiment, for an IPAD tablet, the standard 30-pin dock extender cables and 30-pin digital AV cables, when connected to the IPAD's docking connector, extend outward from the IPAD by a distance greater than 25 mm. The reorienting connector assembly of the invention in one or more embodiments extends approximately 9 mm and allows those cables to be more compactly enclosed by the tablet enclosure as shown in FIGS. 24 and 25.

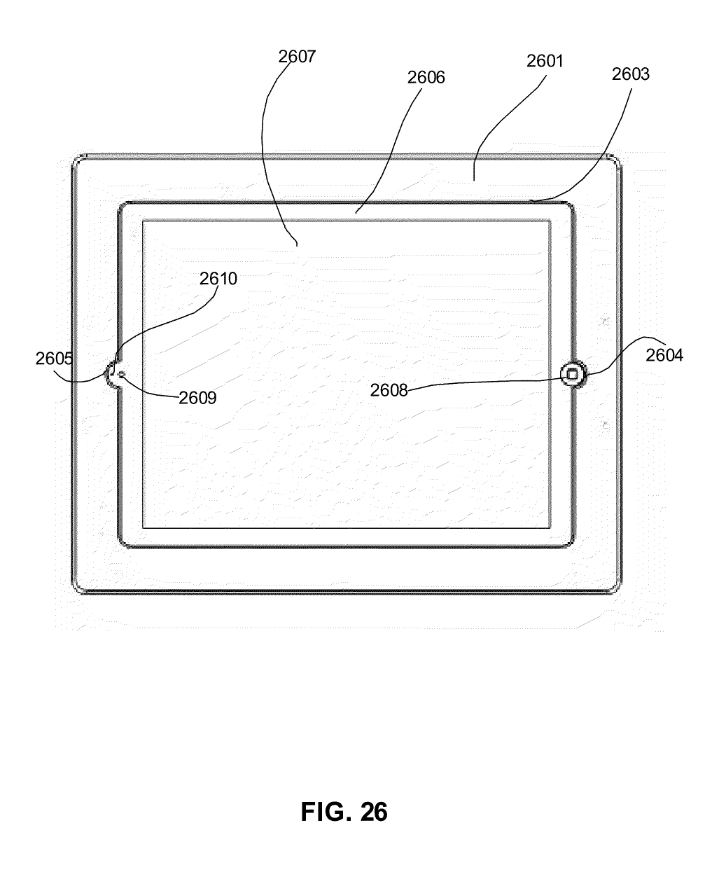

FIG. 26 is a front view of a tablet enclosure in accordance with an exemplary embodiment. The tablet enclosure comprises faceplate 2601. In accordance with at least one embodiment, faceplate 2601 includes an aperture 2603 through which at least a portion display 2607 may be accessed. In accordance with at least one embodiment, at least a portion of a face 2606 of the tablet device may also be accessed through aperture 2603. In accordance with at least one embodiment, an indentation 2604 is included to allow access to button 2608. In accordance with at least one embodiment, an indentation 2605 is included to allow access to camera 2609 and/or proximity sensor 2610.

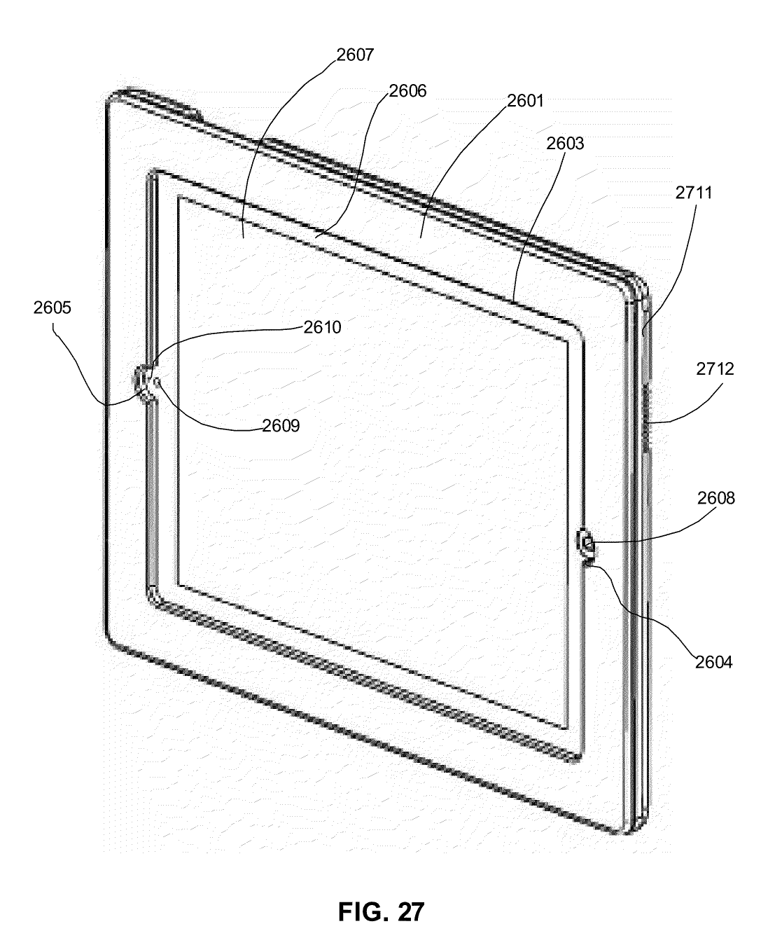

FIG. 27 is a perspective view of a tablet enclosure in accordance with an exemplary embodiment. In accordance with at least one embodiment, faceplate 2601 is coupled to rear housing 2711. In accordance with at least one embodiment, rear housing 2711 includes speaker grille 2712.

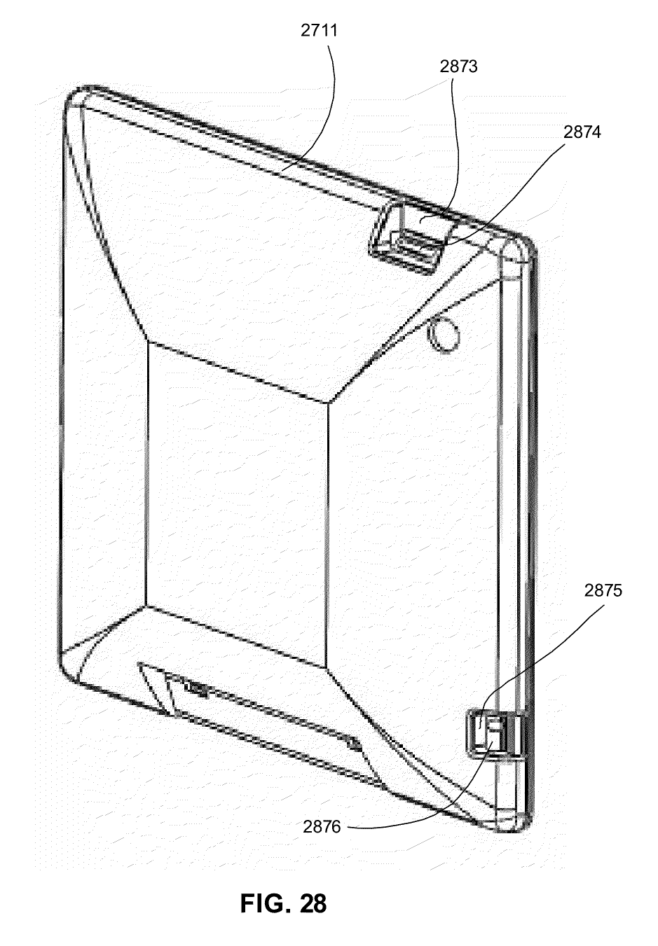

FIG. 28 is a perspective view of a tablet enclosure in accordance with an exemplary embodiment. In accordance with at least one embodiment, rear housing 2711 includes indentation 2873 to allow access to control features (e.g. a volume control) 2874 of a tablet device. In accordance with at least one embodiment, rear housing 2711 includes indentation 2875 to allow access to a connector 2876 of a tablet device.

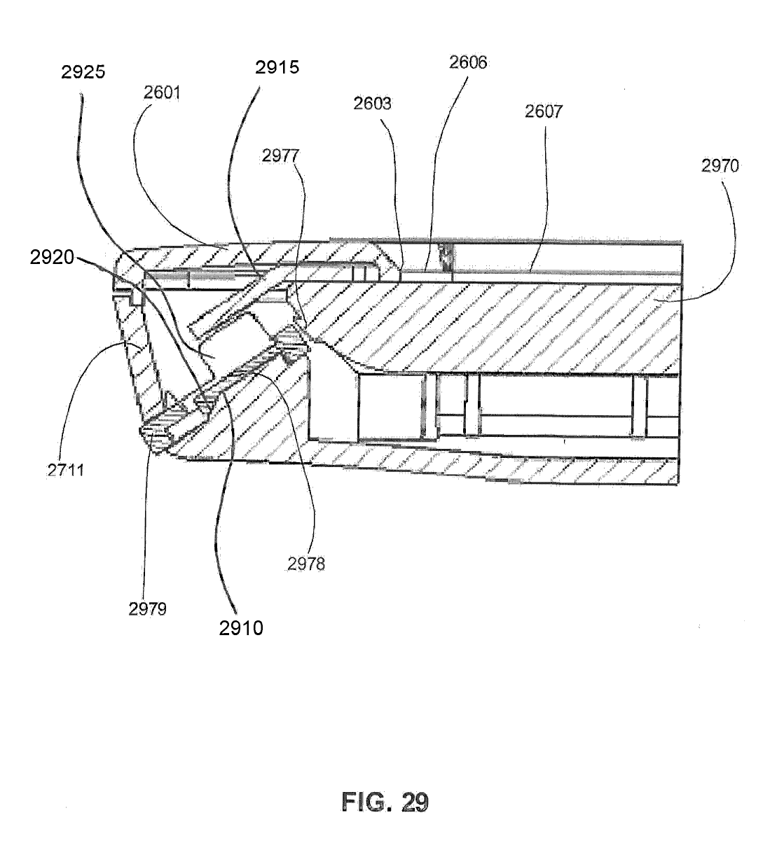

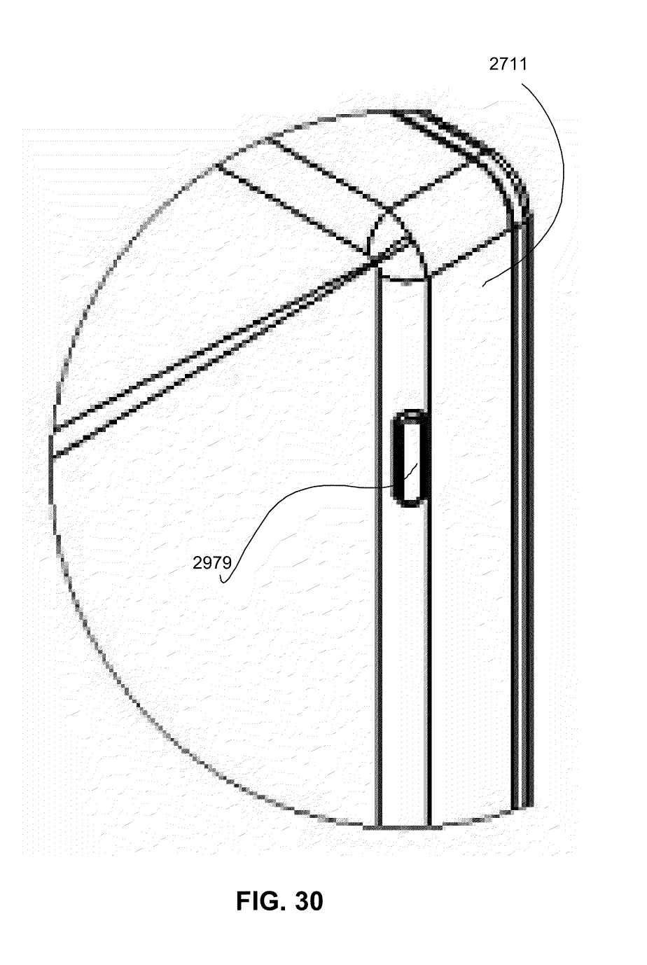

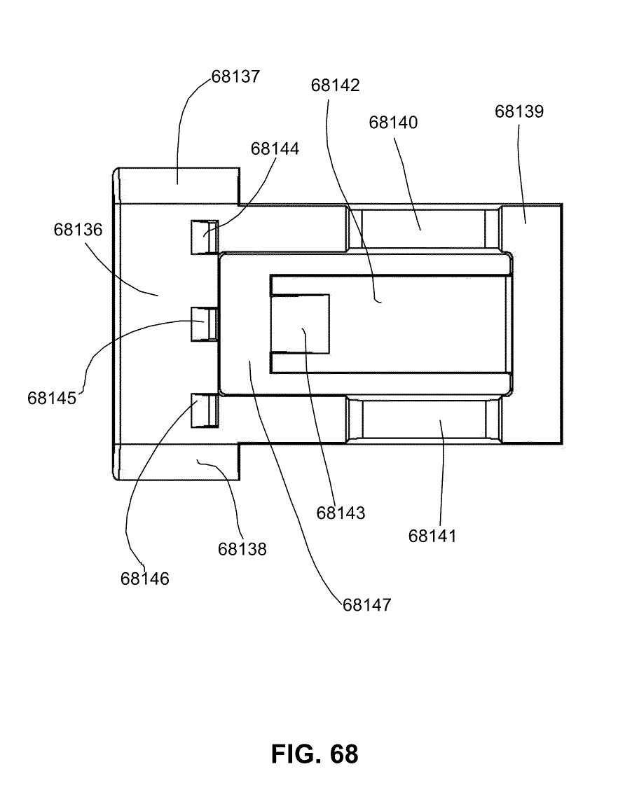

FIG. 29 is a top cross sectional view of a tablet enclosure in accordance with an exemplary embodiment comprising a control linkage. In accordance with at least one embodiment, the tablet device comprises a housing 2970 and a button 2977. In accordance with at least one embodiment, control linkage 2978 is provided in rear housing 2711 of the tablet enclosure. Control linkage 2978 is configured to cause depression of button 2977 of the tablet device upon depression of button 2979 of the tablet enclosure, which may be disposed along an edge of rear housing 2711, as shown in FIG. 30. In the embodiment of FIG. 29, linkage 2978 (which may for example be a molded plastic (e.g. polycarbonate) linkage) is disposed adjacent to a ramp portion 2910 of rear housing 2711 and a restraining member 2915. In one or more embodiments, restraining member is integrally formed with the metal retainer of the tablet enclosure. Linkage 2978 (described in greater detail below with respect to FIGS. 68-70) includes an inclined surface 2920 that engages ramp 2910. Button 2979, linkage 2978, restraining member 2915 and ramp 2910 are configured such that pushing button 2979 pushes linkage 2978 towards tablet button 2977, causing inclined surface 2920 of linkage 2978 to ride up ramp 2910, creating a restoring force against linkage 2978, biasing linkage 2978 towards its retracted position away from tablet button 2977 such that linkage 2978 and button 2979 return to their original, retracted positions when button 2979 is released.

FIG. 68 is a top view of a control linkage for a tablet enclosure in accordance with at least one embodiment. The control linkage, which in one or more embodiments is molded as a single plastic component, comprises button 68136, button edge 68137, button edge 68138, actuator 68139, tab 68140, tab 68141, flexible linkage 68142, beveled indentation 68143, beveled tab 68144, beveled tab 68145, and beveled tab 68146. In accordance with at least one embodiment, the control linkage of FIG. 68 may be used to activate a control feature of an enclosed tablet device from the exterior of the tablet enclosure. In one or more embodiments, the control linkage is made of a self-lubricating polymer to minimize friction and preserve tactile response of the button on the tablet device actuated by the control linkage.

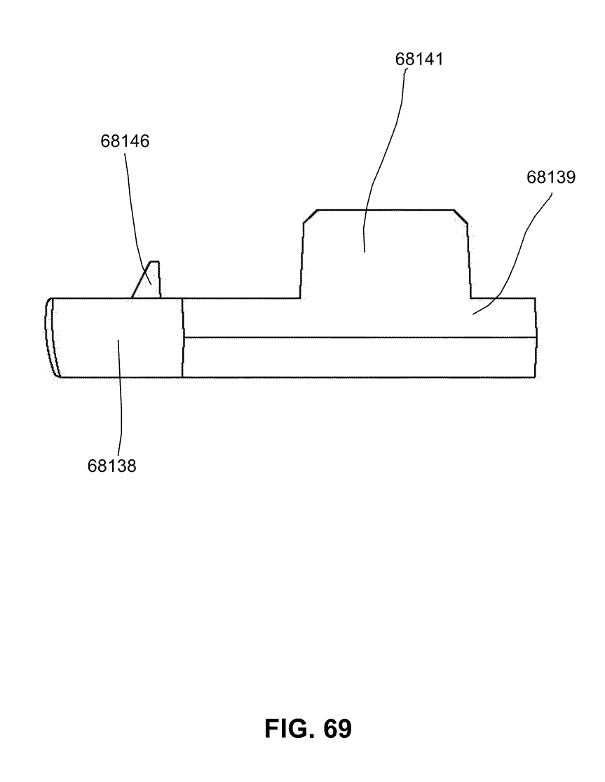

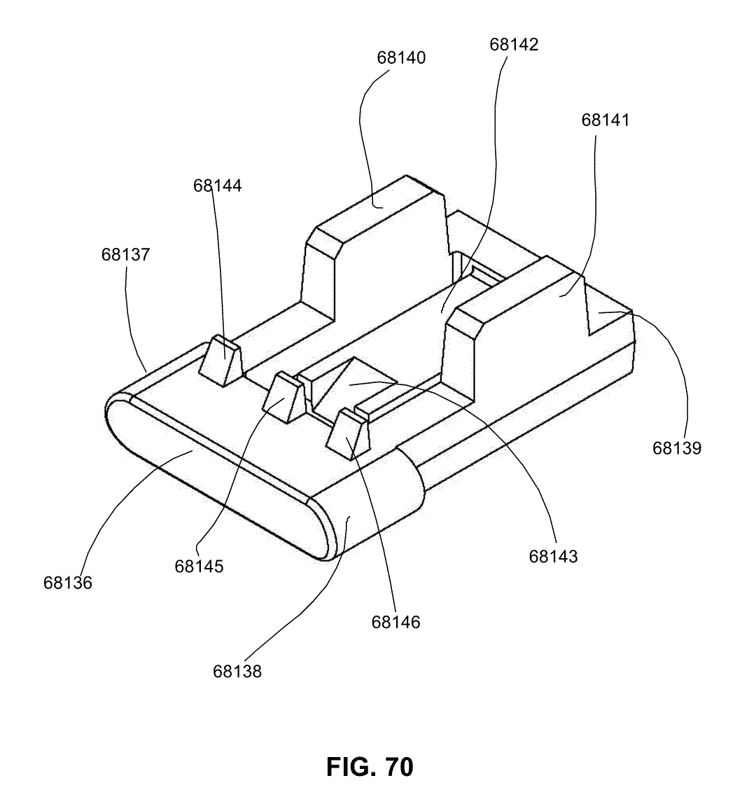

FIGS. 69 and 70 provide side and perspective views, respectively, of the control linkage of FIG. 68.

In one or more embodiments of the tablet enclosure that are configured to enclose an IPAD tablet, the user control features of the IPAD are accessible through the rear housing of the enclosure to provide the user the ability to interface/control any or all of the user functions and keys in accordance with Apple's Case Design Guidelines for Apple Devices, Release R2. These include features along the side of the product (e.g. Volume button, Sleep/Wake button, side switch, 3.5 mm audio jack), on the rear (e.g. Camera), and on the front of the product (e.g. Home button, front camera and proximity sensor/ambient light sensor).

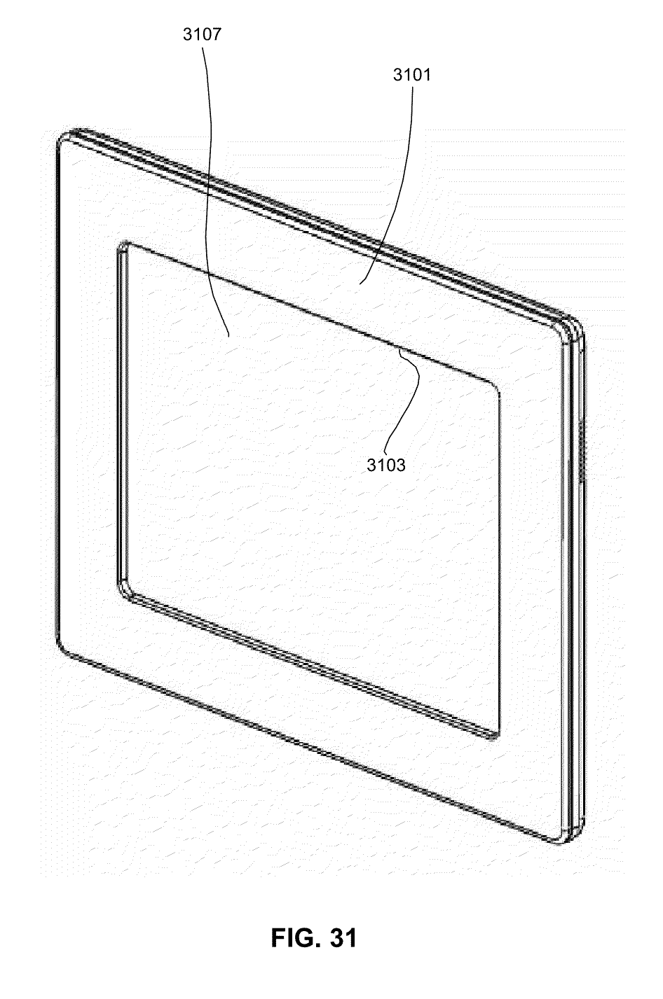

Access to any or all of the enclosed tablet's control features may be limited or prevented by enclosing them and not providing access through the rear housing or faceplate. FIGS. 31 to 33 show a configuration where no external control feature is available to the user or individuals. This option would appeal to open public settings such as schools, libraries, or in commercial settings like kiosks and trade shows.

FIG. 31 is a perspective view of a tablet enclosure in accordance with an exemplary embodiment. In accordance with at least one embodiment, the tablet enclosure comprises a faceplate 3101 which includes an aperture 3103 which allows access to display 3107 of the tablet device, but does not allow access to other control features.

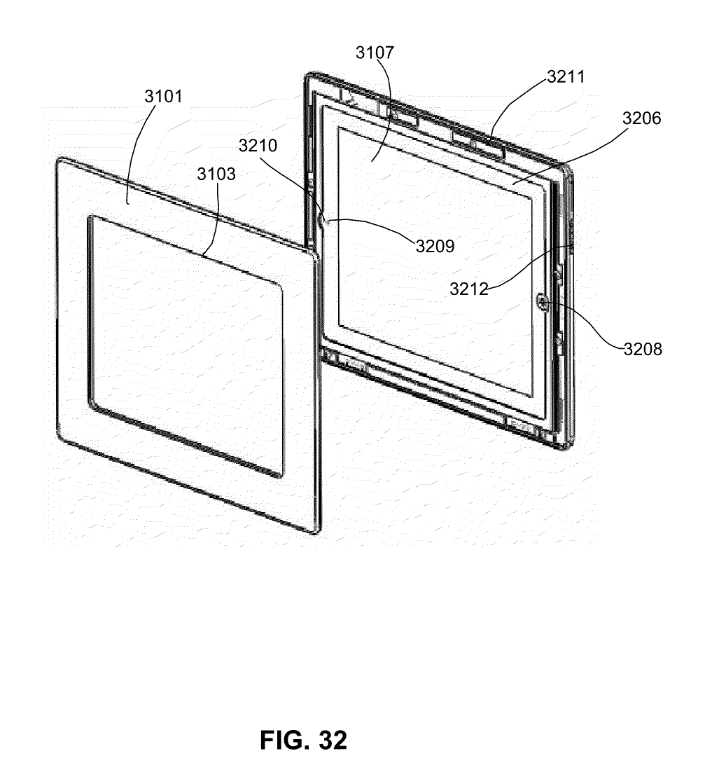

FIG. 32 is an exploded perspective view of a tablet enclosure in accordance with an exemplary embodiment. In accordance with at least one embodiment, the tablet enclosure comprises rear housing 3211, which couples to faceplate 3101 to enclose a tablet device. In accordance with at least one embodiment, the tablet device comprises face 3206, button 3208, camera 3209, and/or microphone 3210 in addition to display 3107. In one or more embodiments, faceplate 3103 is configured to allow access to display 3107 but not to other control features of the tablet device.

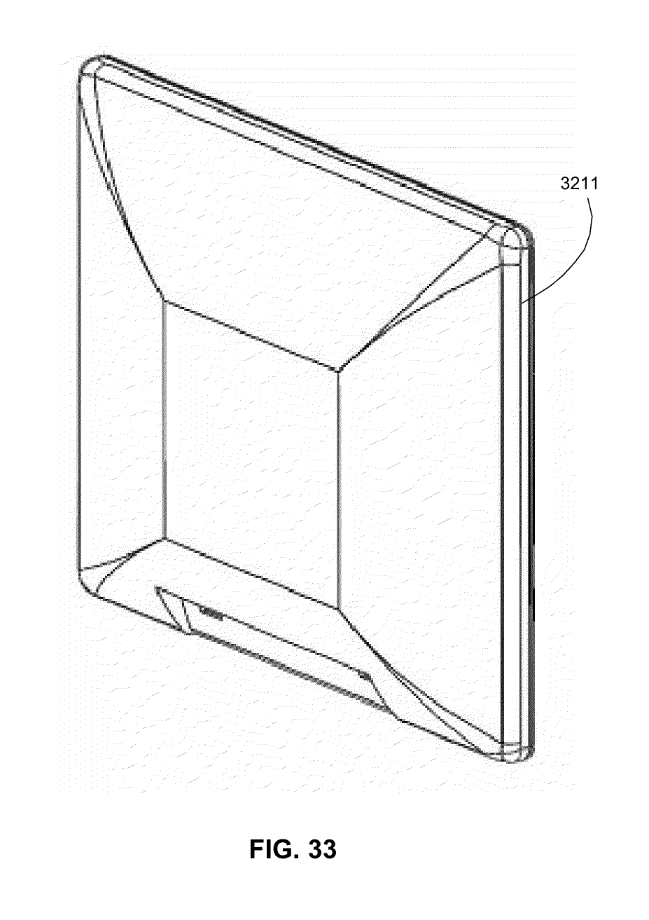

FIG. 33 is a perspective view of a tablet enclosure in accordance with an exemplary embodiment enclosing a tablet device that does not allow access to rear or side tablet control features.

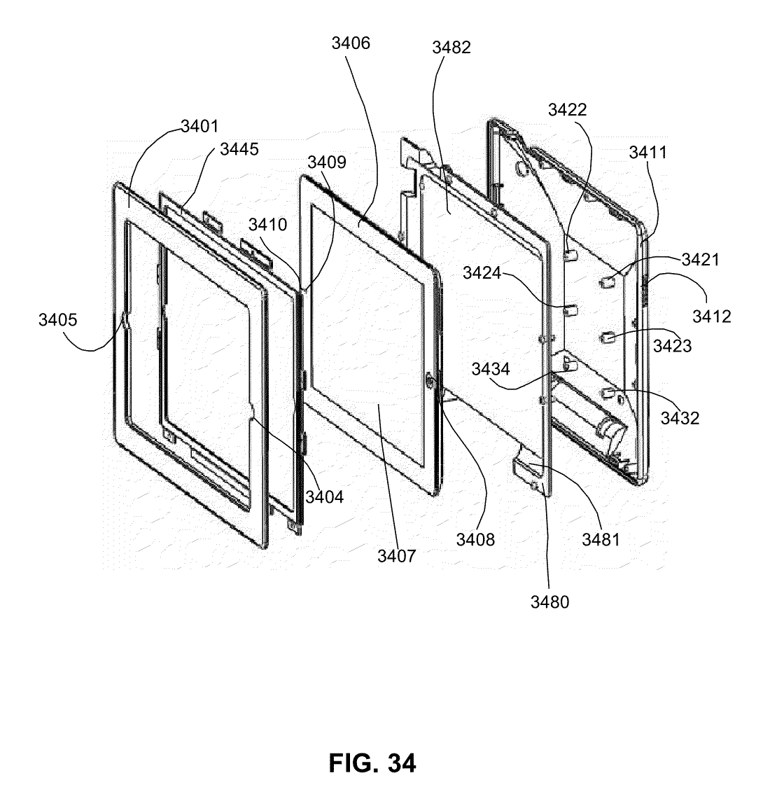

In one or more embodiments, the tablet enclosure of the present invention includes an internal adapter that is used to allow tablets having different physical configurations to be mounted inside the enclosure. FIG. 34 is an exploded perspective view of a tablet enclosure in accordance with an exemplary embodiment. In accordance with at least one embodiment, the tablet enclosure comprises a faceplate 3401, a stamped metal retainer 3445, an adapter plate 3482, and a rear housing 3411. In accordance with at least one embodiment, adapter plate 3482 includes sidewall 3481 and flange 3480. In accordance with at least one embodiment, sidewall 3481 separates flange 3480 from adapter plate 3482 a distance that allows the tablet device to fit snugly between back plate panel 3482 and faceplate 3401. In accordance with at least one embodiment, rear housing 3411 includes holes 3421, 3422, 3423, 3424, 3432, and 3434 to allow mounting of the rear of rear housing 3411 to a surface or other mounting structure. Either or both of the size of the back plate panel 3482 and/or the depth of the back plate relief 3481 may be changed to adapt the tablet enclosure to a wide variety of tablet devices of diverse sizes and depths.

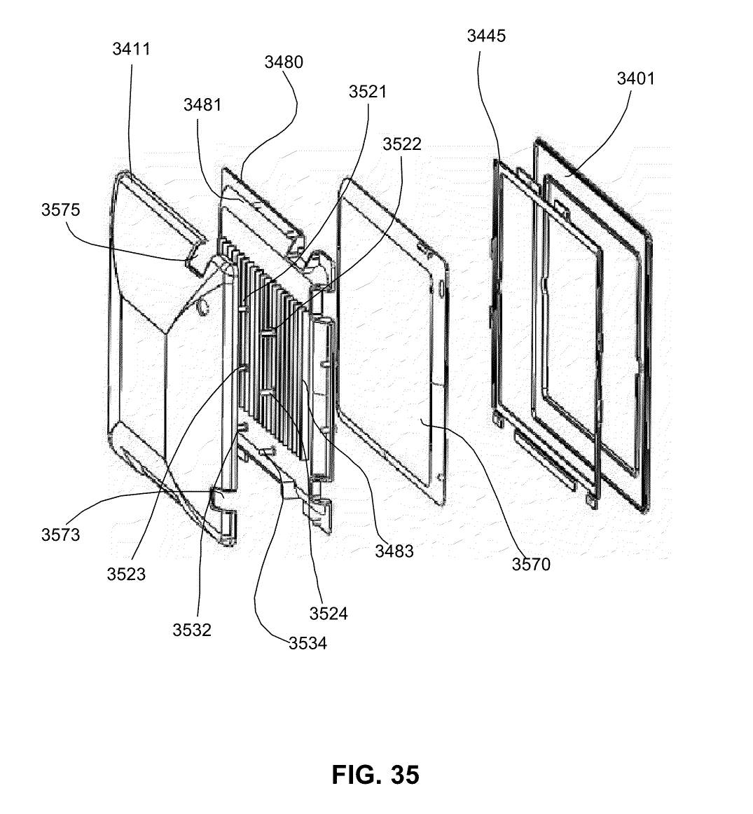

FIG. 35 is an exploded perspective view of a tablet enclosure in accordance with an exemplary embodiment. In accordance with at least one embodiment, rear housing 3411 includes indentation 3575 and indentation 3573 to allow access to connectors and/or control buttons of a tablet device. In accordance with at least one embodiment, adapter plate 3482 comprises reinforcements 3483 and holes 3521, 3522, 3523, 3524, 3532, and 3534 which may, for example, include threaded inserts and/or molded threads. In accordance with at least one embodiment, the tablet device comprises a rear housing 3570. The adapter as shown in FIGS. 34 and 35 is configured to accommodate one or more tablet configurations.

In addition to internally securing the tablet device to the tablet enclosure of the invention, in one or more embodiments that include a tabletop stand, the stand includes security provisions to allow the stand to be securely mounted to a tabletop or other surface or structure.

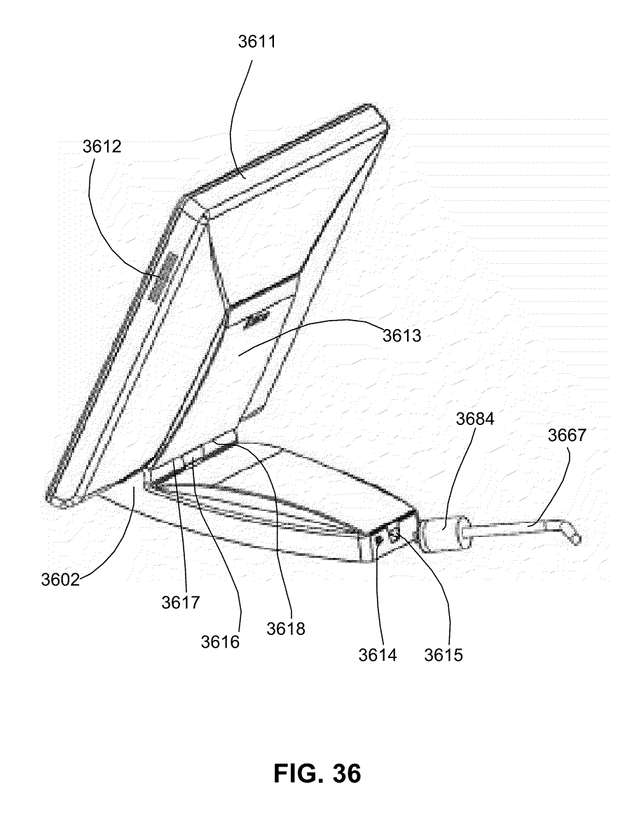

FIG. 36 is a perspective view of a tablet enclosure and stand in accordance with an exemplary embodiment enclosing a tablet device and comprising a security slot. The base assembly includes a KENSINGTON security slot 3614 to allow the use of a cabled KENSINGTON lock to affix the stand to a mounting surface. In accordance with at least one embodiment, the tablet enclosure comprises rear enclosure 3611, which includes speaker grille 3612. In accordance with at least one embodiment, the tablet enclosure comprises panel 3613 attached to the rear of rear housing 3611. In accordance with at least one embodiment, rear housing 3611 is coupled to hinge portion 3616, which is coupled to hinge portions 3617 and 3618 of stand 3602. In accordance with at least one embodiment, stand 3602 comprises slot 3614 and indentation 3615. In accordance with at least one embodiment, stand 3602 allows cable 3667 to be coupled to the tablet device but to extend below the stand through an opening in the mounting surface so that cable 3667 remains enclosed and protected from tampering.

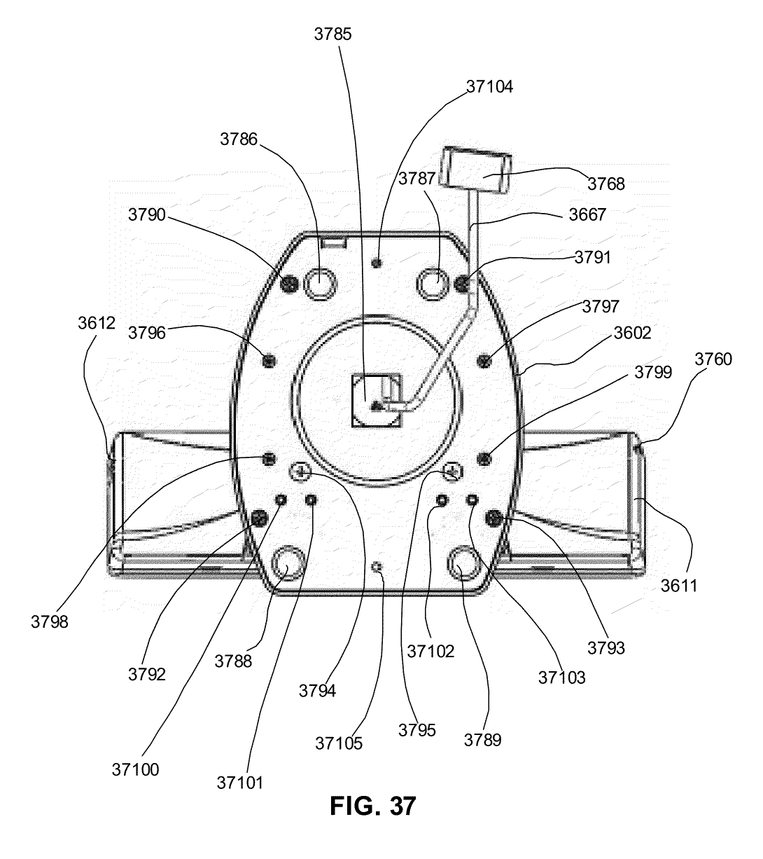

FIG. 37 is a bottom view of a tablet enclosure and stand in accordance with an exemplary embodiment. In accordance with at least one embodiment, stand 3602 comprises a base plate attached to an upper portion of stand 3602 by screws 3790, 3791, 3792, and 3793. In accordance with at least one embodiment, the base plate is provided with feet 3786, 3787, 3788, and 3789. In accordance with at least one embodiment, feet 3786, 3787, 3788, and 3789 are rubber (e.g., synthetic rubber) feet. In accordance with at least one embodiment, the base plate of the stand 3602 includes holes 37100, 37101, 37102, and 37103 which help secure hinge portions of the stand 3602. In accordance with at least one embodiment, an aperture 3785 is included in a central region of the base plate of stand 3602 to allow cable 3667 to pass downward through the base plate of the stand 3602. In accordance with at least one embodiment, cable 3667 may pass through a surface, for example, a table or a desk, underlying the base plate. In accordance with at least one embodiment, cable 3667 is terminated in a connector 3768. In accordance with at least one embodiment, holes 3794 and 3795 are provided to allow secure mounting of stand 3602 to a surface using screws or other fasteners. In accordance with at least one embodiment, the base plate of stand 3602 includes holes 37104 and 37105 to support other mounting options.

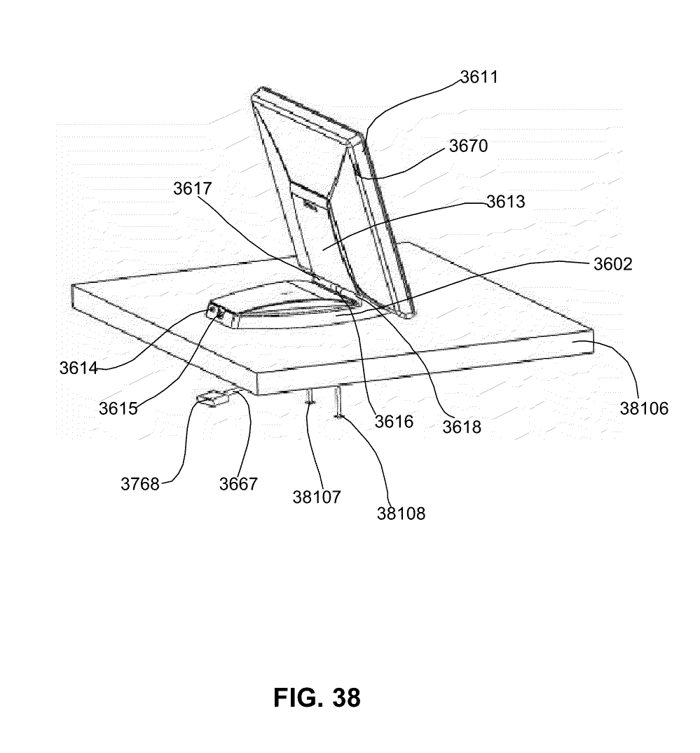

FIG. 38 is a perspective view of a tablet enclosure and stand in accordance with an exemplary embodiment enclosing a tablet device and comprising threaded receptacles to receive stand mounting screws. In accordance with at least one embodiment, stand 3602 is mounted on a surface 38106 using screws 38107 and 38108. In accordance with at least one embodiment, surface 38106 is a tabletop. In accordance with at least one embodiment, surface 38106 is a desktop. In accordance with at least one embodiment, surface 38106 is a countertop. In accordance with at least one embodiment, surface 38106 is an audiovisual (AV) equipment cart top. In accordance with at least one embodiment, surface 38106 is a ceiling or a wall.

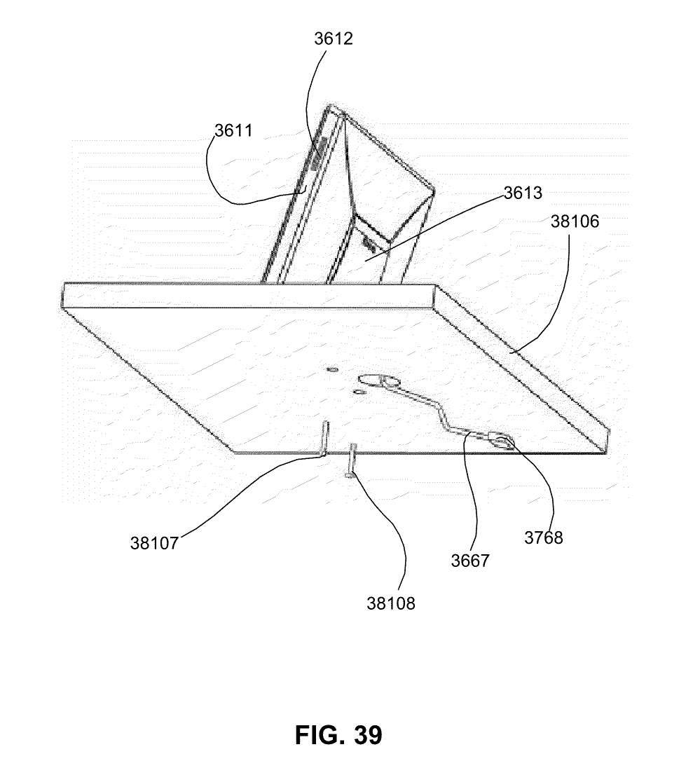

FIG. 39 is a bottom perspective view of a tablet enclosure and stand in accordance with an exemplary embodiment comprising threaded receptacles to receive stand mounting screws 38107 and 38108. FIG. 39 also shows how cable 3667 may pass from the bottom of the stand through an opening in the mounting surface 38106, such as, for example, a table or desktop.

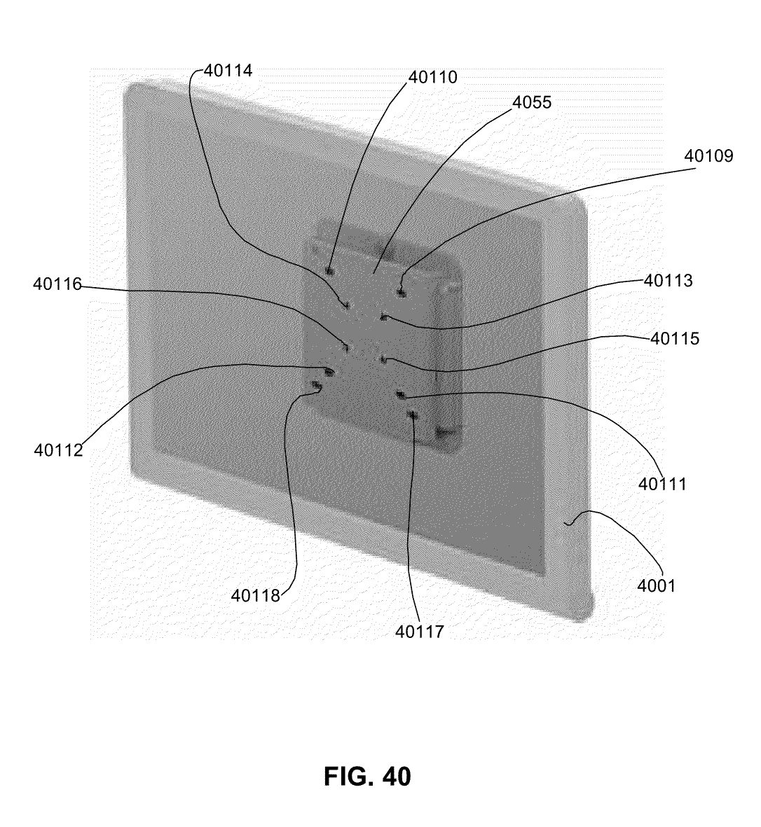

FIG. 40 is a partially transparent perspective view showing a reinforcing mounting plate 4055 according to one or more embodiments of the invention. Plate 4055, which may be metal, may be disposed adjacent the rear housing of the invention to provide reinforcement and rigidity to the rear housing and to provide strengthened mounting provisions. In the embodiment of FIG. 40, plate 4055 includes several sets of holes (which may be threaded or include threaded inserts) 40109, 40110, 40111, and 40112 to allow mounting of tablet enclosure 4001 to various types of mounts and supports. In accordance with at least one embodiment, holes 40109, 40110, 40111, and 40112 are arranged in a rectangular pattern. In accordance with at least one embodiment, plate 4055 includes holes 40113, 40114, 40115, and 40116 to allow mounting of tablet enclosure 4001 with a different hole configuration than that of holes 40109, 40110, 40111, and 40112. In accordance with at least one embodiment, holes 40113, 40114, 40115, and 40116 are arranged in a rectangular pattern. In accordance with at least one embodiment, plate 4055 includes holes 40117 and 40118. In accordance with at least one embodiment, holes 40117 and 40118 allow mounting of tablet enclosure 4001 with a configuration different from either that of holes 40109, 40110, 40111, and 40112 and also holes 40113, 40114, 40115, and 40116. In accordance with at least one embodiment, holes 40117 and 40118 may be used in conjunction with at least a subset of holes 40109, 40110, 40111, and 40112. In accordance with at least one embodiment, holes 40117 and 40118 may be used in conjunction with at least a subset of holes 40113, 40114, 40115, and 40116.

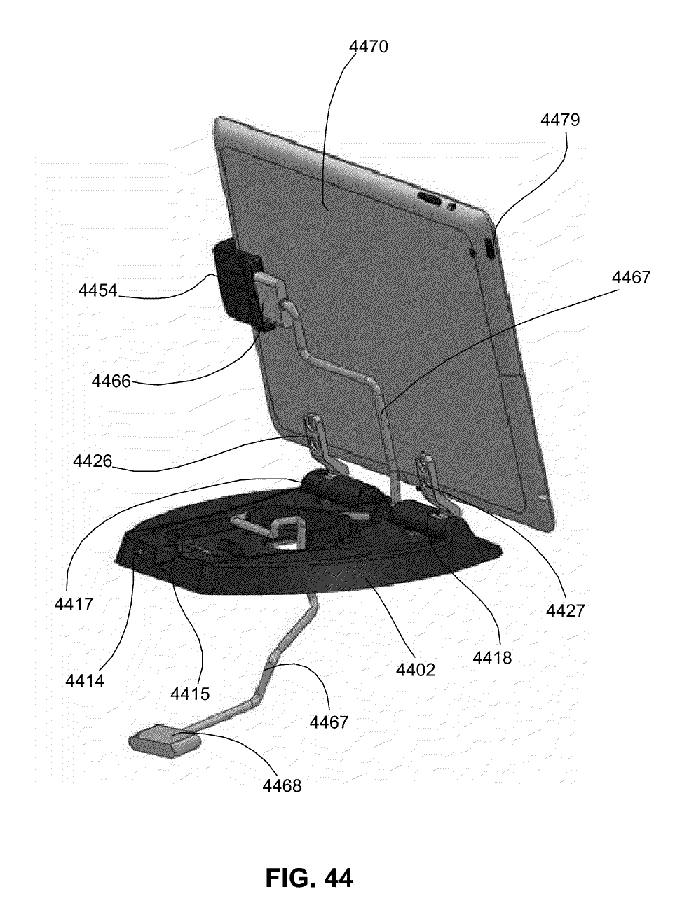

FIG. 44 is a perspective cut-away view of an exemplary embodiment of a tablet enclosure and stand depicting cable routing inside the enclosure in accordance with at least one embodiment. In accordance with at least one embodiment, the enclosed tablet comprises a rear housing 4470 and a button 4479. In accordance with at least one embodiment, stand 4402 comprises slot 4414, indentation 4415, hinges 4417 and 4418, and hinge arms 4426 and 4427. In accordance with at least one embodiment, reorienting connector assembly 4454 is coupled to the tablet and to connector 4466, which is coupled to cable 4467. In accordance with at least one embodiment, reorienting connector assembly 4454 allows cable 4467 to lie along the rear housing 4470 of the tablet inside the tablet enclosure. In accordance with at least one embodiment, cable 4467 is routed between hinges 4417 and 4418. In accordance with at least one embodiment, cable 4467 is routed through a trough molded in stand 4402. In accordance with at least one embodiment, cable 4467 is bent several times until it passes through an aperture in stand 4402. In accordance with at least one embodiment, cable 4467 is coupled to connector 4468 outside of stand 4402. In accordance with at least one embodiment, hinge arm 4426 is coupled to hinge 4417 and hinge arm 4427 is coupled to hinge 4418.

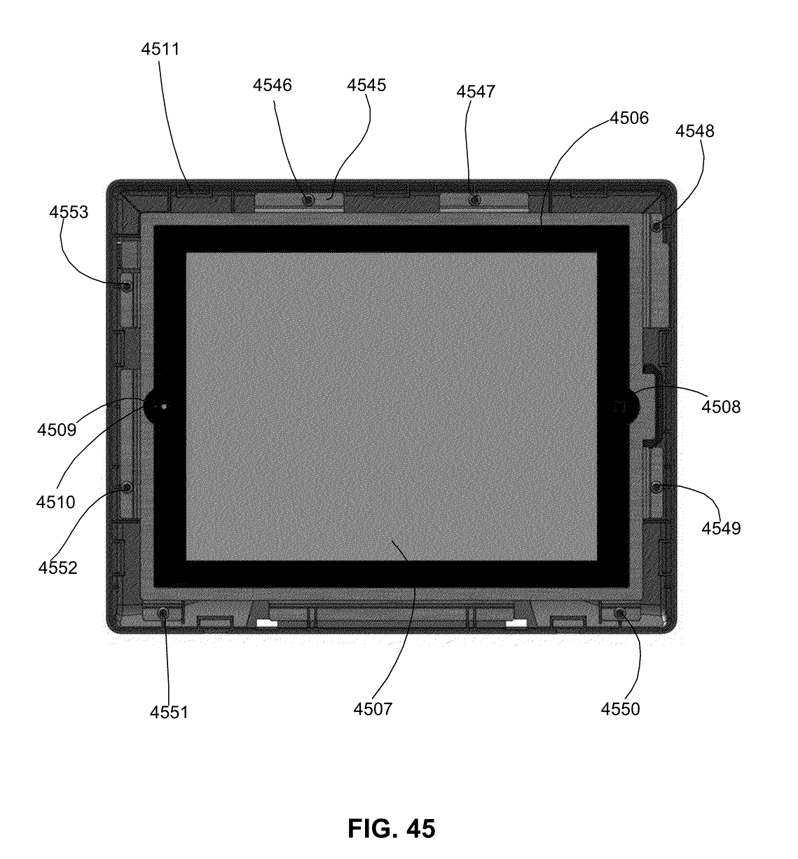

FIG. 45 is a front view of a tablet enclosure depicting a stamped metal retainer to securely retain a tablet device in accordance with at least one embodiment. In accordance with at least one embodiment, the tablet device comprises a display 4507 disposed within a face 4506. In accordance with at least one embodiment, the tablet device comprises a button 4508 situated in faceplate 4506. In accordance with at least one embodiment, the tablet device comprises a camera 4509 situated in face 4506. In accordance with at least one embodiment, the tablet device comprises a proximity sensor 4510 situated in face 4506. In accordance with at least one embodiment, a stamped metal retainer 4545 is applied over the tablet device to enclose and secure the tablet device within a tablet enclosure comprising rear housing 4511. Stamped metal retainer 4545 includes a plurality of holes 4546, 4547, 4548, 4549, 4550, 4551, 4552, and 4553 which attach stamped metal retainer 4545 to rear housing 4511.

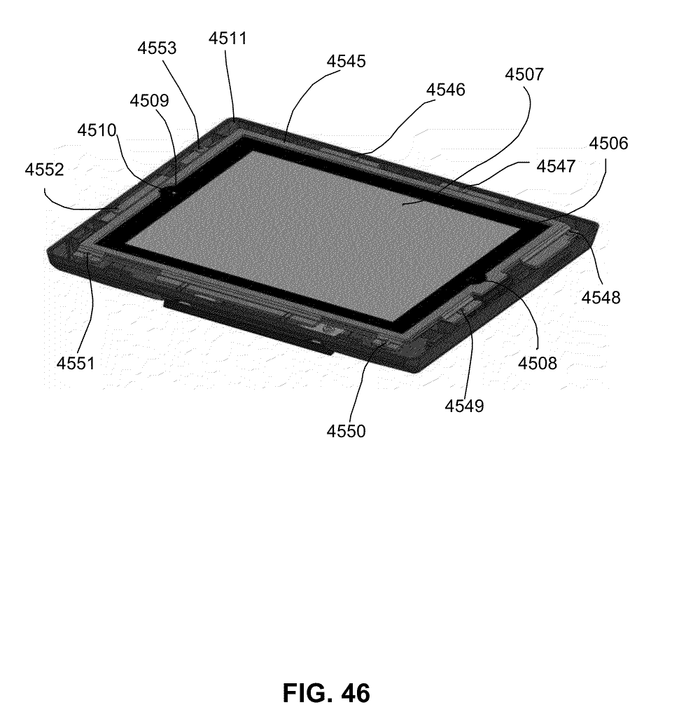

FIG. 46 is a perspective view of a tablet enclosure depicting a stamped metal retainer to securely retain a tablet device in accordance with at least one embodiment.

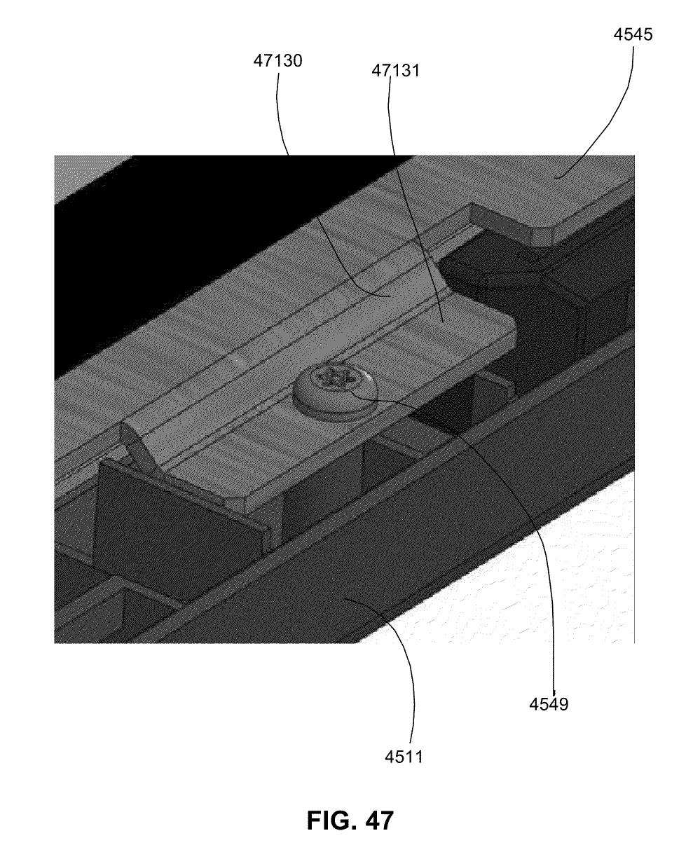

FIG. 47 is a detail perspective view of a portion of a tablet enclosure depicting a portion of a stamped metal retainer to securely retain a tablet device in accordance with at least one embodiment. In accordance with at least one embodiment, tamper-resistant screw 4549 retains tab 47131 against rear housing 4511. In accordance with at least one embodiment, tab 47131 is integrally formed with stamped metal retainer 4545.

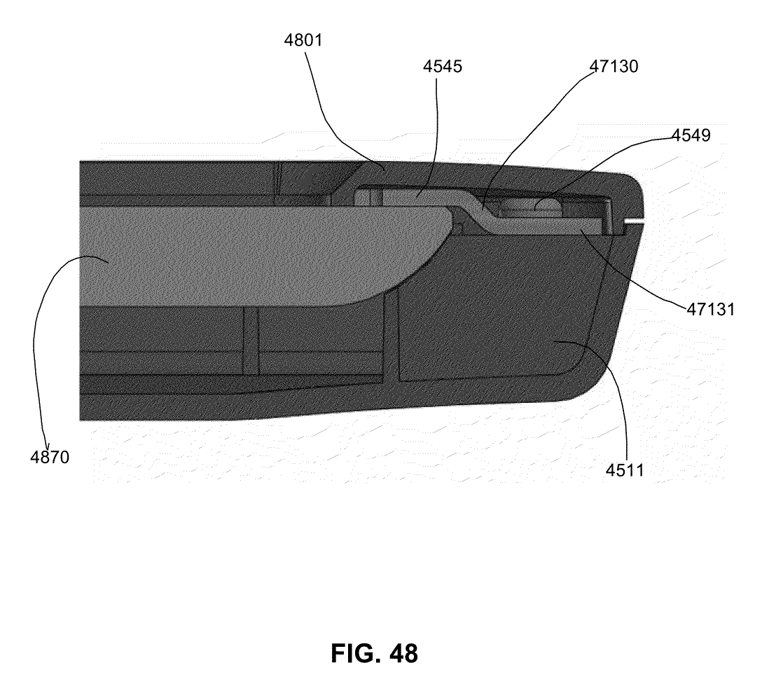

FIG. 48 is a detail cross sectional view of a portion of a tablet enclosure depicting a portion of a stamped metal retainer to securely retain a tablet device in accordance with at least one embodiment. In accordance with at least one embodiment, faceplate 4801 is applied over screw 4549 to conceal screw 4549 and reduce the opportunity for tampering. In accordance with at least one embodiment, screw 4549 retains tab 47131 of metal retainer 4545 against rear housing 4511.

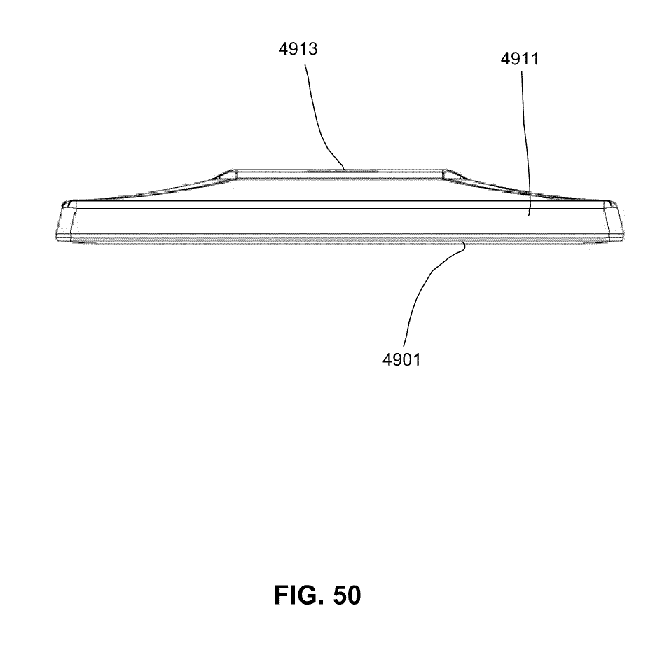

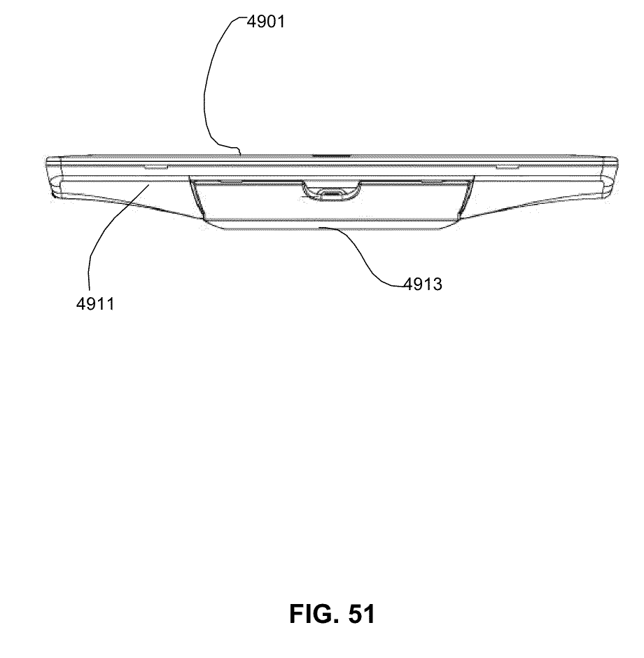

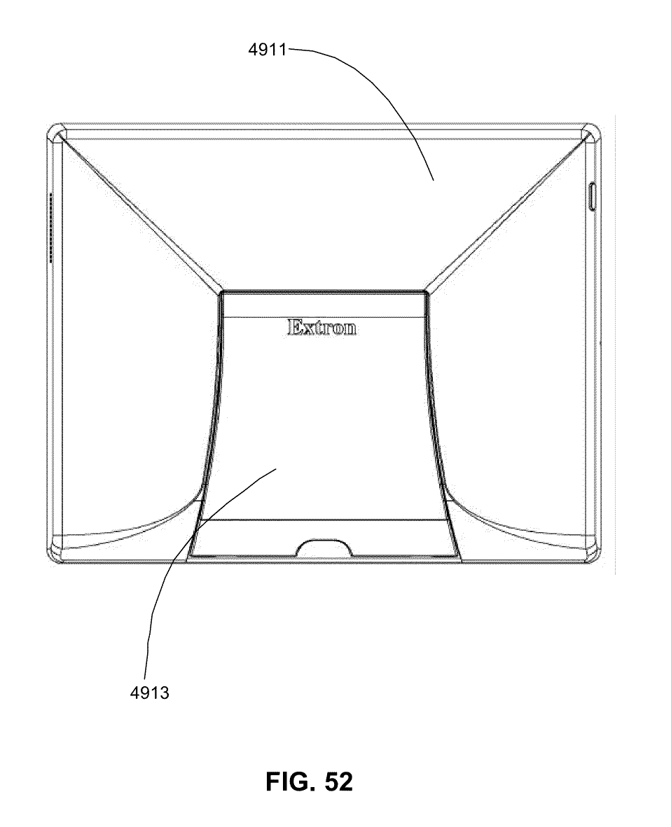

Additional views of and embodiment of a tablet enclosure of the invention are provided in FIGS. 49-53. FIG. 49 is a side view of a tablet enclosure in accordance with at least one embodiment. FIG. 50 is a top view of a tablet enclosure in accordance with at least one embodiment. FIG. 51 is a bottom view of a tablet enclosure in accordance with at least one embodiment. FIG. 52 is a rear view of a tablet enclosure in accordance with at least one embodiment. FIG. 53 is a perspective view of a tablet enclosure in accordance with at least one embodiment.

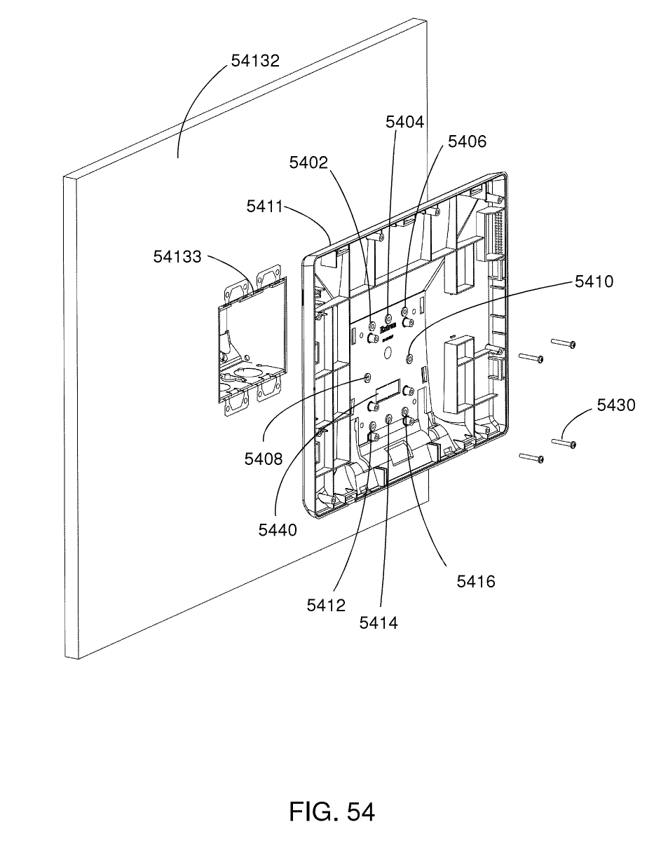

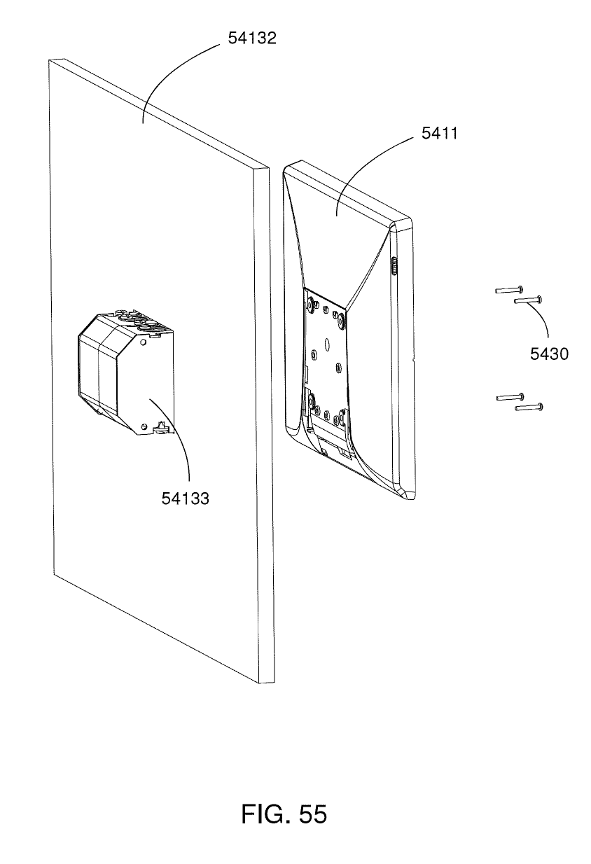

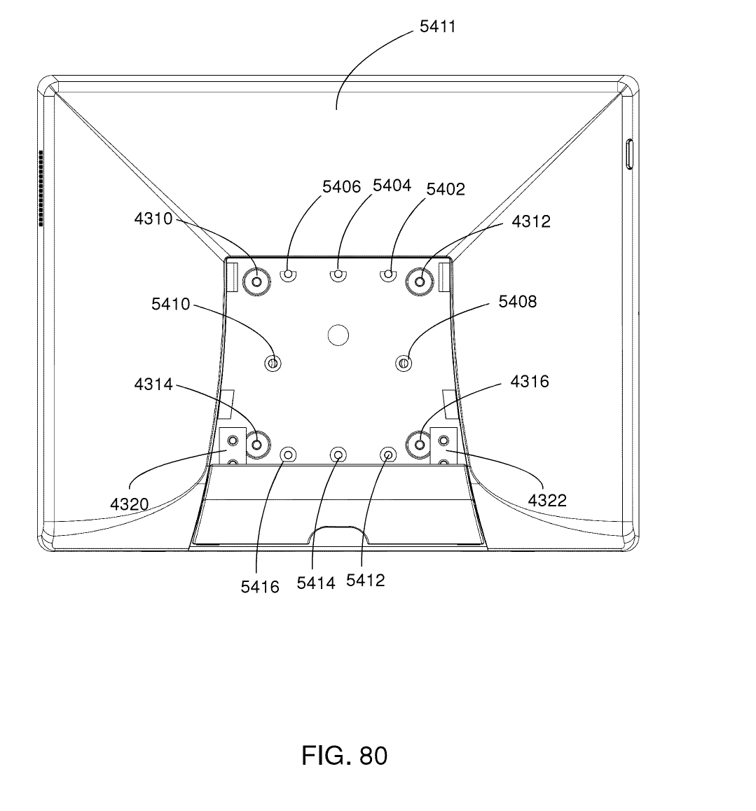

FIGS. 54 and 55 are front and rear perspective views, respectively, of a rear housing of a tablet enclosure suitable for mounting on a surface using a standard electrical box in accordance with at least one embodiment. In accordance with at least one embodiment, the tablet enclosure comprises rear housing 5411. In accordance with at least one embodiment, rear housing 5411 is configured to allow attachment of to a standard electrical box 54133, which may be a single or multiple gang box installed in a mounting surface 54132, which may, for example, be a wall. In the embodiment of FIG. 54, rear housing 5411 is provided with a number of mounting holes 5402, 5404, 5406, 5408, 5410, 5412, 5414 and 5416 that provide for mounting rear housing 5411 to various electrical box configurations. In one or more embodiments, mounting holes 5402, 5406, 5412 and 5416 are configured so as to allow mounting to a standard two-gang electrical junction box using, for example, screws 5430. In one or more embodiments, mounting holes 5404 and 5414 are configured so as to allow mounting to a standard single gang electrical junction box, and mounting holes 5408 and 5410 are configured to allow mounting to a standard European single-gang electrical junction box. In one or more embodiments, as shown in FIG. 80, rear housing 5411 is provided with multiple mounting provisions, including mounting holes 5402, 5404, 5406, 5408, 5410, 5412, 5414, and 5416 for mounting to standard electrical junction boxes, threaded mounting holes 4310, 4312, 4314 and 4316 for mounting to VESA mounts, and hinge mounts 4320 and 4322 for mounting to a hinge. As shown in FIG. 54, rear housing 5411 may be provided with a knock-out tab 5440 which allows cabling to pass through rear housing 5411 into junction box 54133. In one or more embodiments, a reinforcing mounting plate (for example plate 4055 of FIG. 40) is configured with similar mounting holes may be disposed adjacent to rear housing 5411 to provide additional rigidity and strength.

In one or more embodiments, a tablet housing of the invention is mounted to an electrical junction box by attaching rear housing 5411 (which may include a reinforcing mounting plate) to an electrical junction box using screws 5430. A tablet device is placed into rear housing 5411, and then the remainder of the tablet housing of the invention, comprising, for example, a tablet device retainer and a front plate, are assembled to rear housing 5411, thereby securely attaching the tablet housing and the tablet device to the electrical junction box.

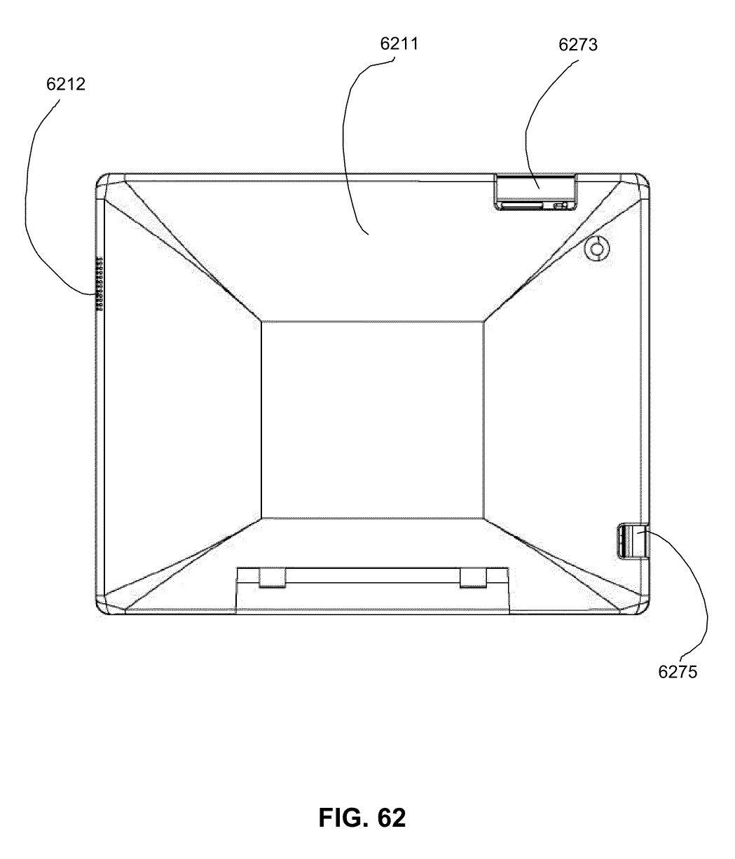

FIG. 62 is a rear view of a tablet enclosure in accordance with at least one embodiment. In accordance with at least one embodiment, the tablet enclosure comprises rear portion 6211. In accordance with at least one embodiment, speaker grille 6212, indentation 6273, and/or indentation 6275 are provided in rear portion 6211.

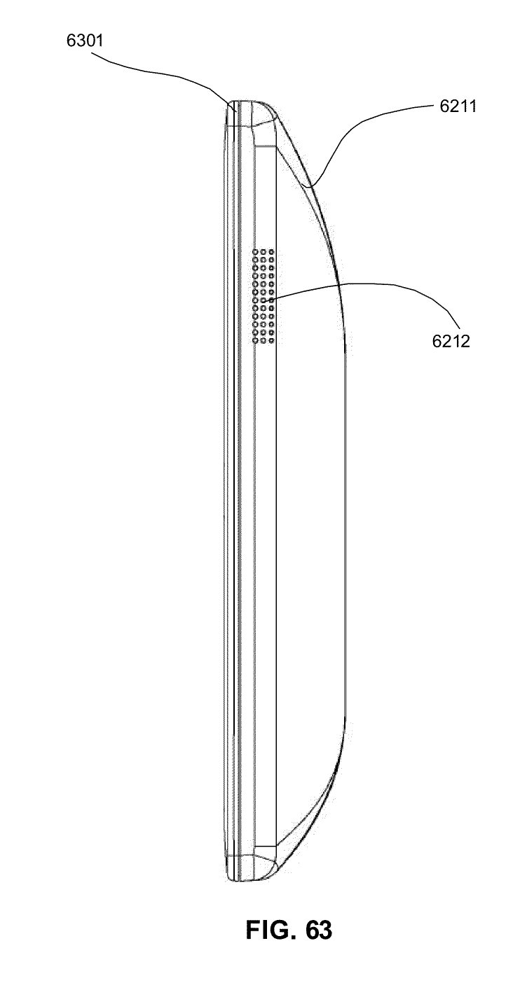

FIG. 63 is a side view of a tablet enclosure in accordance with at least one embodiment. In accordance with at least one embodiment, faceplate 6301 is coupled to rear portion 6211.

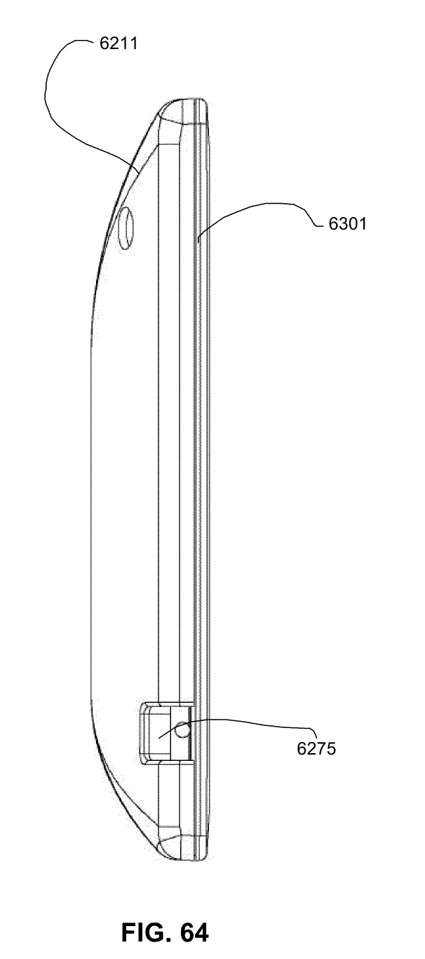

FIG. 64 is a side view of a tablet enclosure in accordance with at least one embodiment.

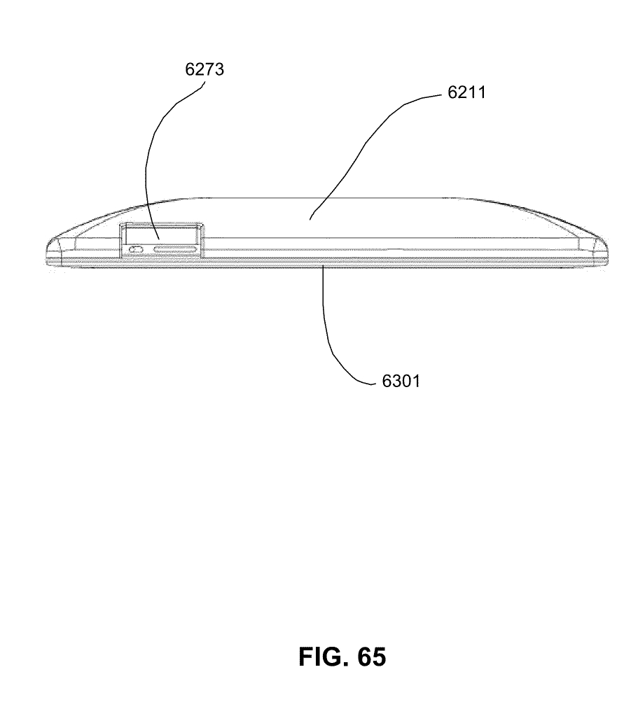

FIG. 65 is a top view of a tablet enclosure in accordance with at least one embodiment.

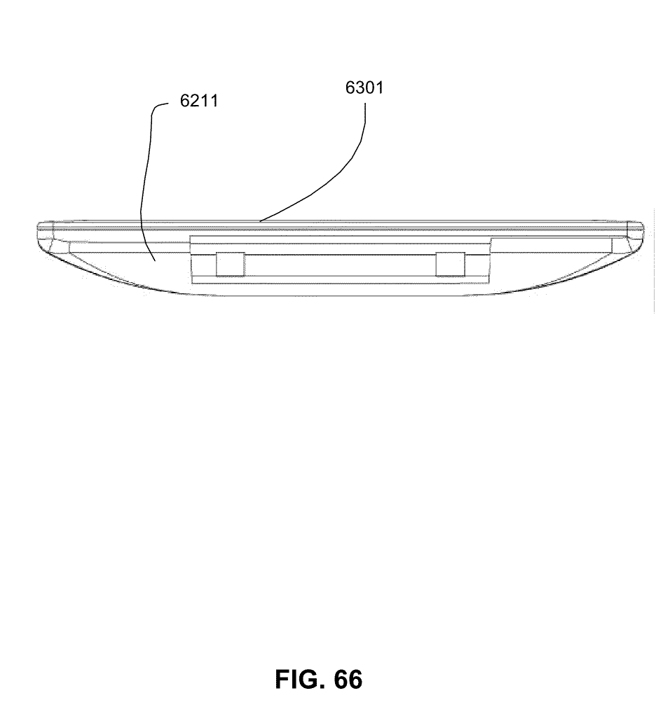

FIG. 66 is a bottom view of a tablet enclosure in accordance with at least one embodiment.

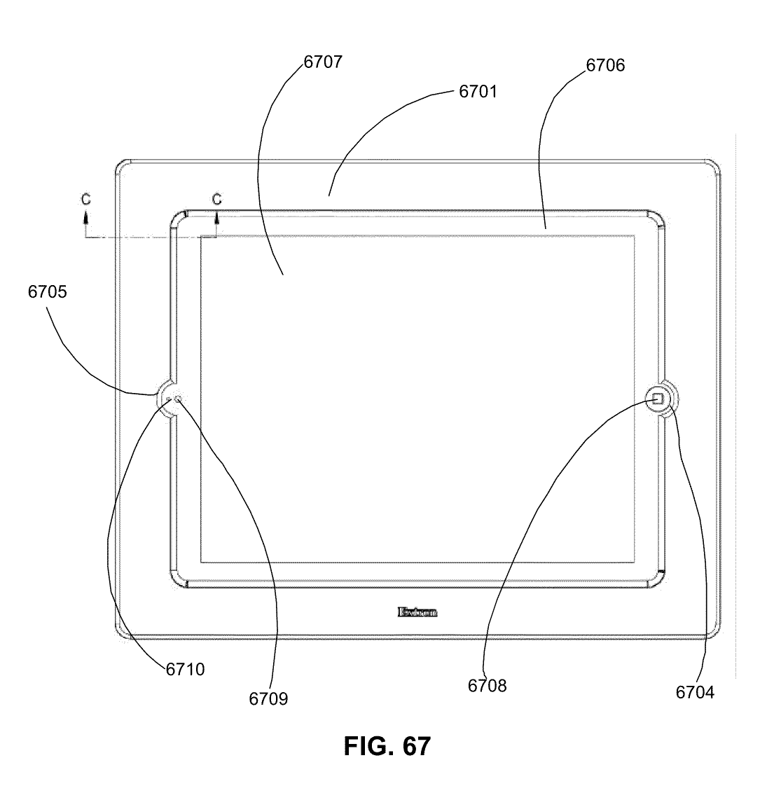

FIG. 67 is a front view of a tablet enclosure in accordance with at least one embodiment. In accordance with at least one embodiment, the tablet enclosure comprises faceplate 6701 which includes an aperture through which display 6707 can be observed. In accordance with at least one embodiment, at least a portion of face 6706 of the tablet device can also be observed through the aperture. In accordance with at least one embodiment, an indentation 6704 is provided in faceplate 6701 to allow clearance for button 6708 to be operated. In accordance with at least one embodiment, an indentation 6705 is provided to allow clearance for camera 6709 and/or proximity sensor 6710. A section line C-C is illustrated to show the orientation of the cross sectional view depicted in FIG. 29.

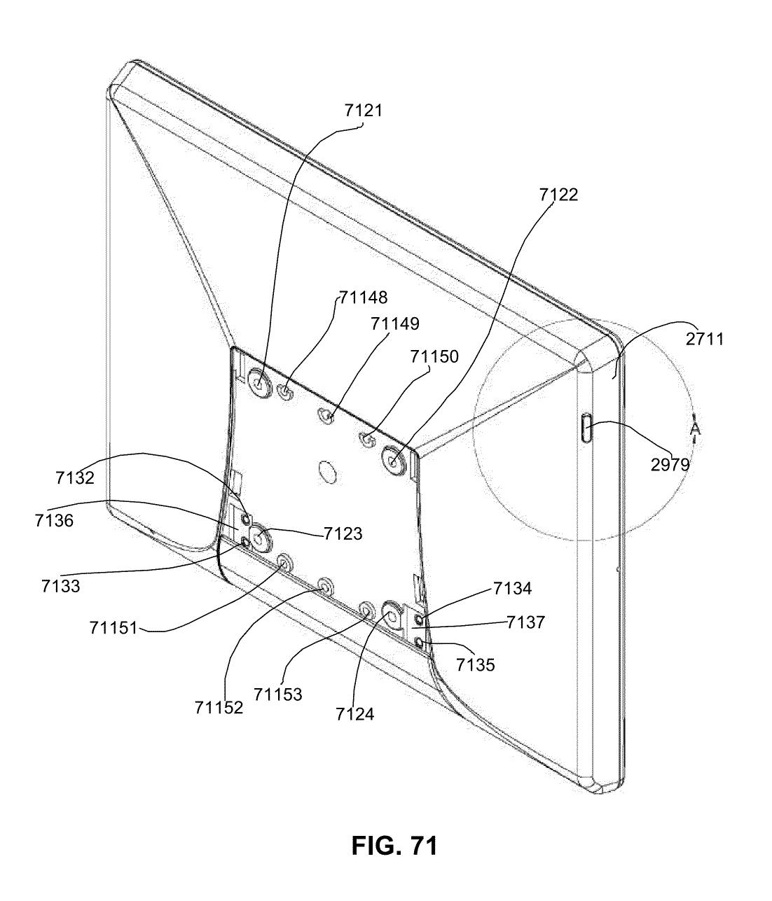

FIG. 71 is a perspective view of a tablet enclosure in accordance with at least one embodiment that provides for mounting to a number of support structures, including a stand, VESA mounts, electrical wall box mounting plates, etc. In accordance with at least one embodiment, the tablet enclosure comprises rear housing 2711 and button 2979. In accordance with at least one embodiment, rear housing 2711 includes holes 7121, 7122, 7123, 7124, 71148, 71149, 71150, 71151, 71152, and 71153. In accordance with at least one embodiment, rear housing 2711 includes holes 7132 and 7133 in hinge mount 7136 and holes 7134 and 7135 in hinge mount 7137.

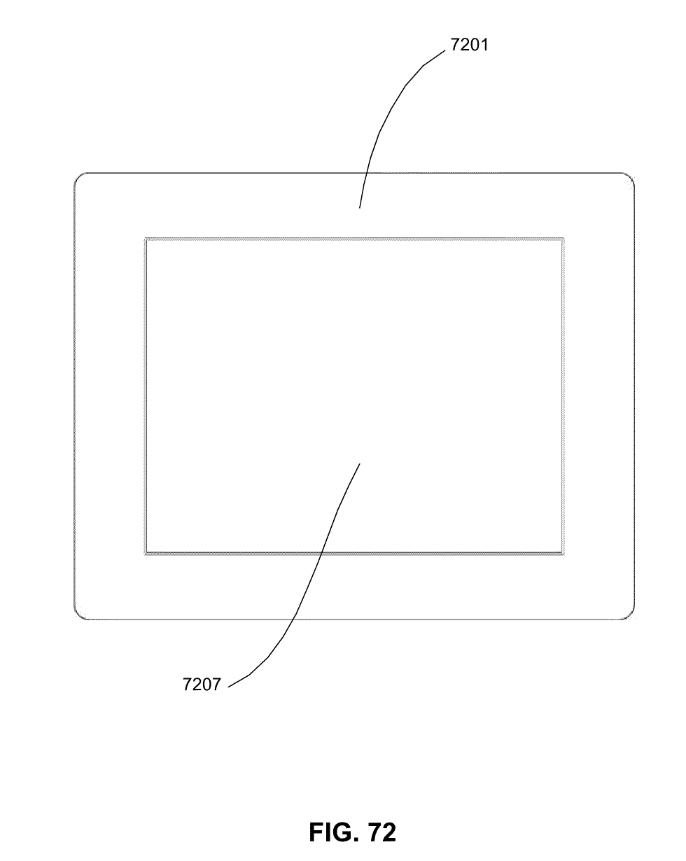

FIG. 72 is a front view of a tablet enclosure in accordance with at least one embodiment. In accordance with at least one embodiment, the tablet enclosure comprises a faceplate 7201 through which display 7207 of a tablet device may be viewed, but which prevents access to other controls on the front of the tablet device.

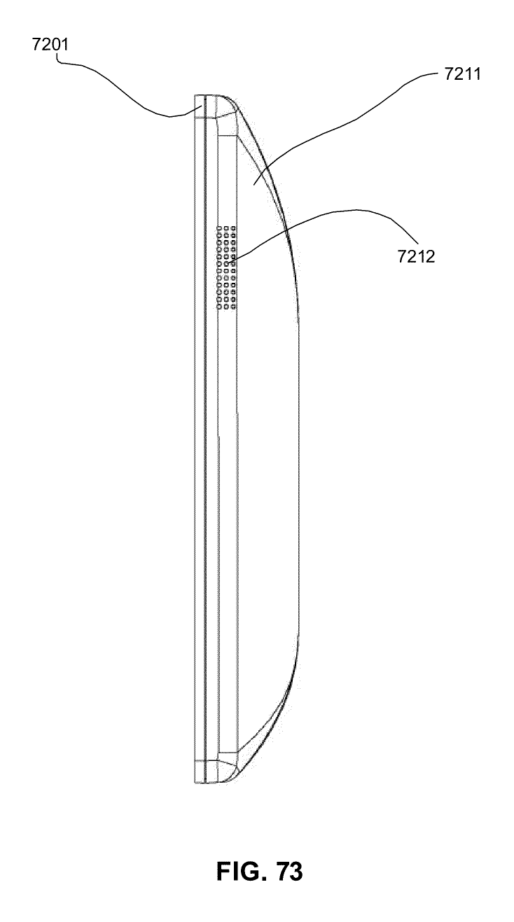

FIG. 73 is a side view of a tablet enclosure in accordance with at least one embodiment. In accordance with at least one embodiment, faceplate 7201 is coupled to rear housing 7211. In accordance with at least one embodiment, rear housing 7211 includes speaker grille 7212 using an array of perforations through rear housing 7211.

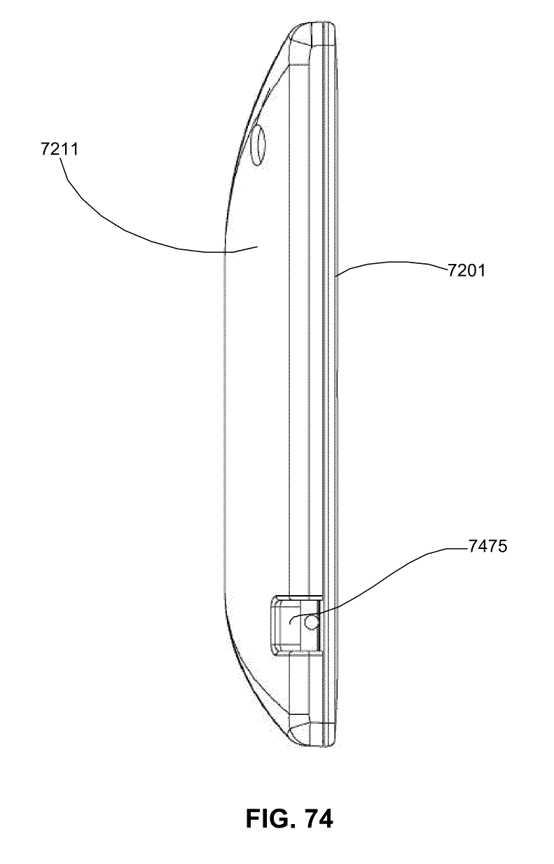

FIG. 74 is a side view of a tablet enclosure in accordance with at least one embodiment. In accordance with at least one embodiment, rear housing 7211 includes an indentation 7475 through rear housing 7211.

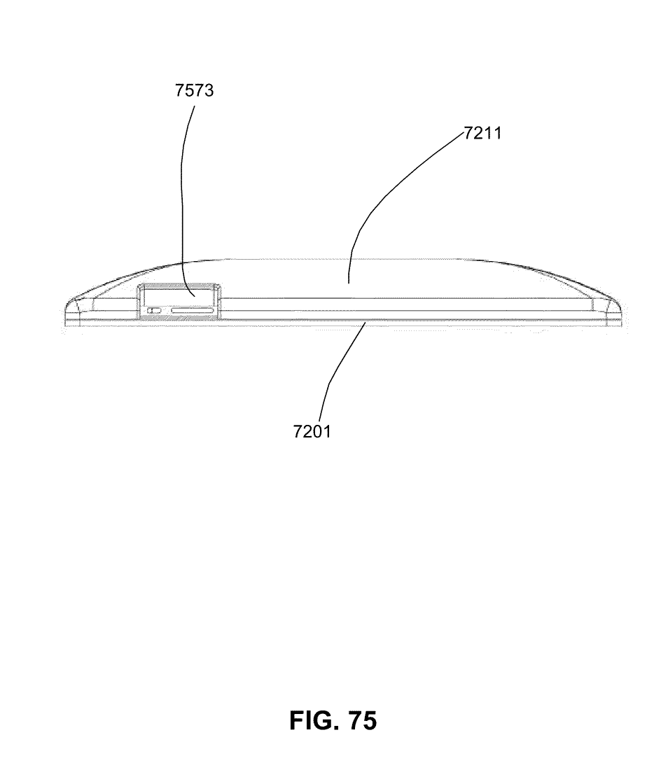

FIG. 75 is a top view of a tablet enclosure in accordance with at least one embodiment. In accordance with at least one embodiment, rear housing 7211 includes an indentation 7573 through rear housing 7211.

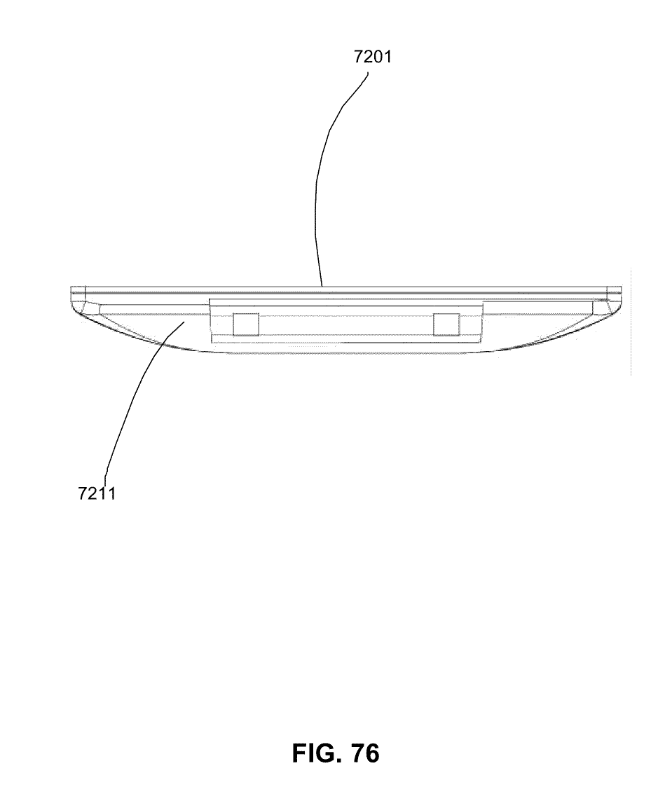

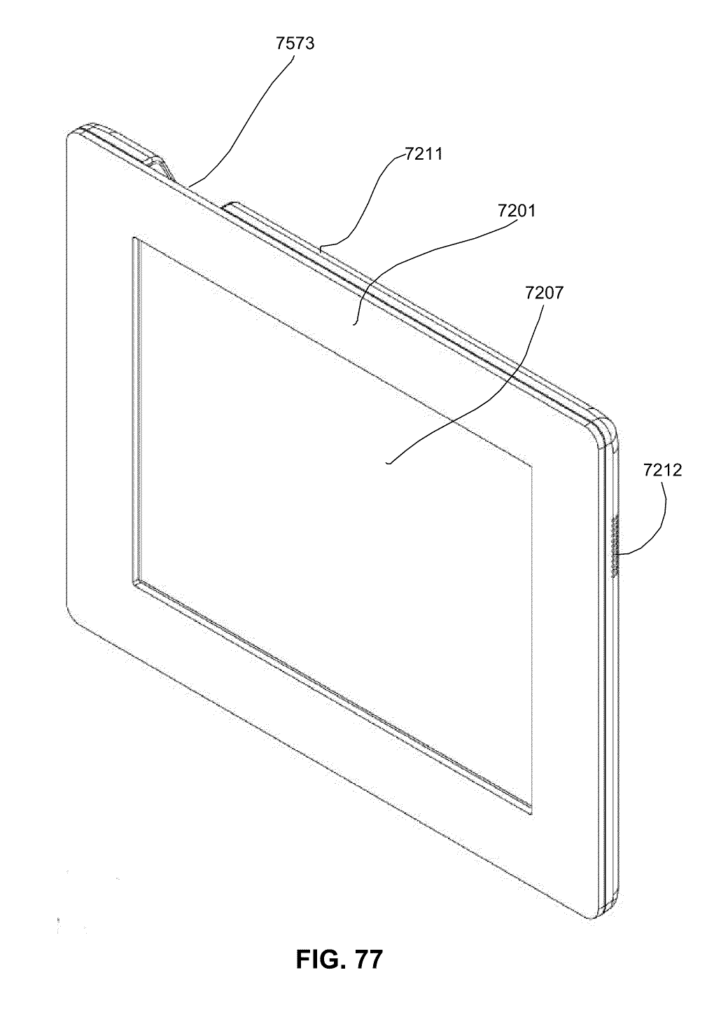

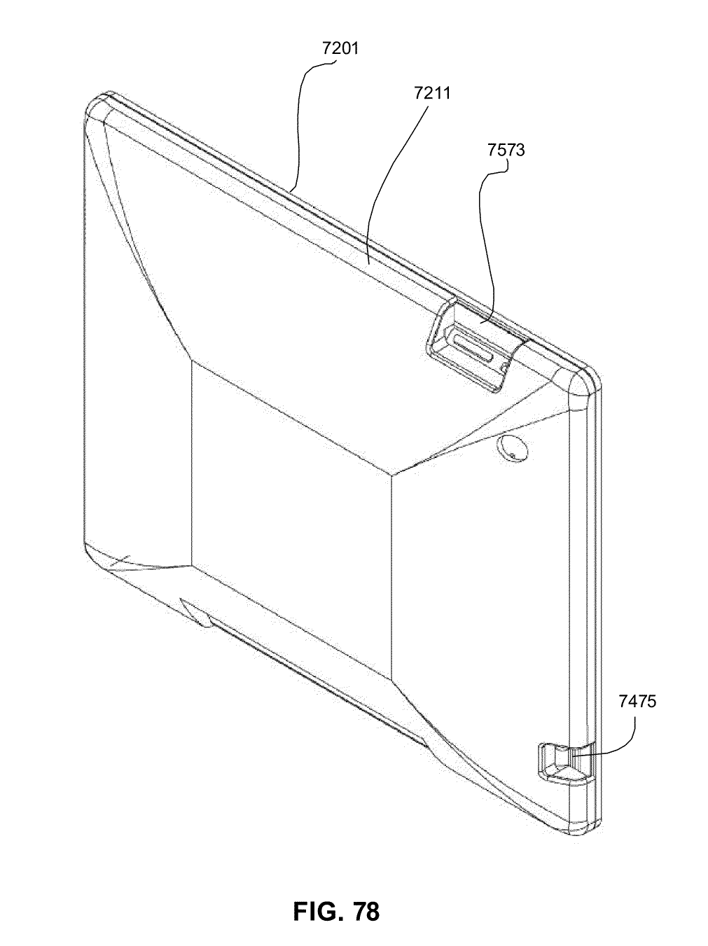

FIGS. 76-78 provide additional views of the tablet enclosure illustrated in FIGS. 72-75. FIG. 76 is a bottom view, FIG. 77 is a front perspective view and FIG. 78 is a rear perspective view of the tablet enclosure.

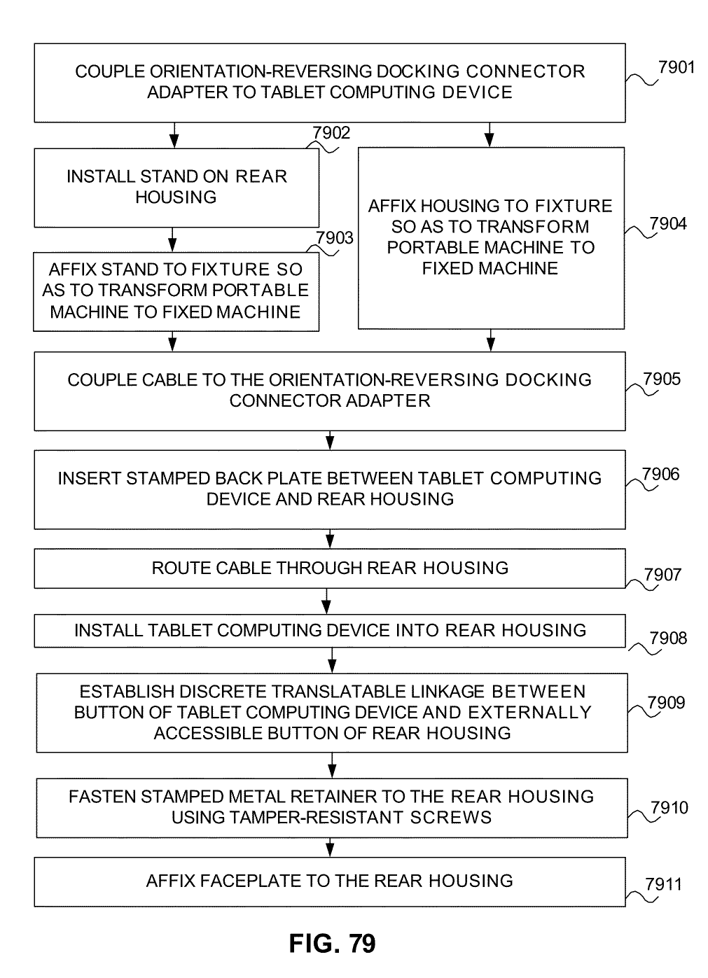

FIG. 79 is a flow diagram illustrating a method for securing a tablet device in accordance with at least one embodiment. In step 7901, an orientation-reversing connector adapter is coupled to a tablet device. From step 7901, the method continues at step 7902 if a stand is to be installed or at step 7904 if not. In step 7902, a stand is installed on the rear housing. From step 7902, the method continues at step 7903. In step 7903, the stand is affixed to a fixture so as to transform the tablet device from being a portable machine to being a fixed machine. The stand is pivotably coupled to the rear housing. From step 7903, the method continues at step 7905. If the stand was not to be installed, the method continues from step 7901 at step 7904. In step 7904, the rear housing is affixed to a fixture so as to transform the tablet device from being a portable machine to being a fixed machine. In step 7905, a cable is coupled to the orientation-reversing connector adapter. In step 7906, a stamped back plate is inserted between the tablet device and the rear housing. The stamped back plate exhibits features in relief. The features in relief define a tablet device usable volume. In step 7907, the cable is routed through the rear housing. In step 7908, the tablet device is installed into the rear housing. In step 7909, a control linkage is established between a button of the tablet device and an externally accessible button of the rear housing. In step 7910, a stamped metal retainer is fastened to the rear housing tamper-resistant screws with the tablet device contained between the stamped metal retainer and the rear housing. In step 7911, a faceplate is affixed to the rear housing.

1. An enclosure for a tablet device comprising:
a rear housing defining a tablet device enclosure volume, said rear housing comprising a control linkage configured to engage a control feature of said tablet device, a first fastener receiving pattern for fixed mounting, and a second fastener receiving pattern for pivotable mounting;
a retainer coupled to said rear housing configured to retain said tablet device within said tablet device enclosure volume;
a faceplate coupled to said rear housing configured to allow access to a predetermined portion of a face of said tablet device.

2. The enclosure of claim 1 further comprising a stand coupled to said enclosure by second fasteners engaging said second fastener receiving pattern.

3. The enclosure of claim 1 wherein said faceplate is configured to be coupled to said retainer.

4. The enclosure of claim 1 wherein said retainer comprises a stamped metal retainer comprising a third fastener receiving pattern and wherein said enclosure further comprises tamper-resistant fasteners engaging said third fastener receiving pattern to affix said stamped metal retainer to said rear housing for providing secure retention of said tablet device.

5. The enclosure of claim 1 wherein said rear housing comprises a removable device adapter, said adapter defining said tablet device enclosure volume.

6. The enclosure of claim 1 wherein said rear housing comprises a reinforcing mounting plate comprising said first fastener receiving pattern.

7. The enclosure of claim 6 wherein said reinforcing mounting plate comprises said second fastener receiving pattern.

8. The enclosure of claim 1 wherein said first fastener receiving pattern is compatible with a VESA standard mount.

9. The enclosure of claim 1 wherein said rear housing comprises a third fastener receiving pattern for mounting to a standard electrical junction box.

10. The enclosure of claim 1 further comprising a reorienting electrical connector configured to reorient an electrical connector port of said tablet device.

11. The enclosure of claim 10 wherein said reorienting electrical connector is configured to reorient a docking port of said tablet device towards an interior of said enclosure.

12. The enclosure of claim 1 wherein said predetermined portion comprises less than an area of a touchscreen of said tablet device.

13. The enclosure of claim 1 wherein said enclosure is configured to prevent access to at least one control feature of said tablet device.

14. The enclosure of claim 13 wherein said enclosure is configured to prevent access to a plurality of control features of said tablet device.

15. A method for securing a tablet device comprising:
coupling a reorienting electrical connector to said tablet device;
coupling a cable to said reorienting electrical connector;
routing said cable through a tablet device enclosure;
installing said tablet device into said enclosure;
affixing said enclosure to a fixture so as to transform said tablet device from a mobile device to a non-mobile device.

16. The method of claim 15 further comprising the step of preventing access to at least one control feature of said tablet device.

17. A method for securing a tablet device to an electrical junction box comprising:
coupling a cable to said tablet device;
routing said cable through a rear housing of a tablet device enclosure;
affixing said rear housing to said electrical junction box;
installing said tablet device into a tablet device volume of said enclosure;
affixing a faceplate over at least a portion of a face of said tablet device.

18. An enclosure for a tablet device comprising a reorienting electrical connector configured to reorient an electrical connector port of said tablet device.

19. The enclosure of claim 18 wherein said reorienting electrical connector is configured to reorient a docking port of said tablet device towards an interior of said enclosure.

20. The enclosure of claim 19 wherein said reorienting electrical connector comprises a flexible printed circuit.
